(19) United States
(12) Patent Application Publication
(10) Pub. No.: US 2011/0089850 A1
(43) Pub. Date: Apr. 21, 2011

(54) LIGHT EMITTING DEVICE AND MANUFACTURING METHOD THEREFOR

(75) Inventors: Akihide Shibata, Osaka (JP); Tetsu Negishi, Osaka (JP); Satoshi Morishita, Osaka (JP); Kenji Komiya, Osaka (JP); Hiroshi Iwata, Osaka (JP); Akira Takahashi, Osaka (JP); Yoshifumi Yaoi, Osaka (JP)

(73) Assignee: Sharp Kabushiki Kaisha, Osaka-shi (JP)

(21) Appl. No.: 12/904,788

(22) Filed: Oct. 14, 2010

(30) Foreign Application Priority Data
Oct. 15, 2009 (JP) 2009-238221
Oct. 15, 2009 (JP) 2009-238224
Jul. 12, 2010 (JP) 2010-157974

(51) Int. Cl. H05B 37/02; H01L 33/00; H01L 33/36

(52) U.S. Cl. 315/250; 438/34; 257/99; 257/E33.001; 257/E33.062; 257/E33.058

(57) ABSTRACT

In a light emitting device, a P-type first region (506) and a P-type third region (508) are placed on both sides of an N-type second region (507) of a rod-like light emitting element (505). Therefore, even if connection of the first, third regions (506, 508) of the rod-like light emitting element (505) relative to the first, third electrodes (1, 3) is reversed, a diode polarity relative to the first, third electrodes (501, 503) is not reversed, making it possible to effectuate normal light emission. Thus, a connection of the first, third regions (506, 508) relative to the first, third electrodes (501, 503) may be reversed during a manufacturing process, making it unnecessary to provide marks or configurations for discrimination of orientation of the rod-like light emitting element (505), so that the manufacturing process can be simplified and manufacturing cost can be cut down.

### TECHNICAL FIELD

The present invention relates to a light emitting device, as well as a manufacturing method therefor, which allows its manufacturing cost to be cut down.

### BACKGROUND ART

As a first conventional light emitting device, heretofore, there has been provided a light emitting device in which a plurality of light emitting diodes are connected in parallel with their polarity uniformized, and driven by DC current (see Patent Literature 1: JP 2007-134430 A). A simplified circuit of this light emitting device is shown in FIG. 17. In the first conventional light emitting device shown in FIG. 17, a plurality of light emitting diodes 101 are connected in parallel so as to be uniform in polarity, and driven by DC current.

However, with the first conventional light emitting device, because of the need for connecting plurality of light emitting diodes 101 in parallel with their polarity uniformized, the manufacturing cost goes high particularly with small decreasing sizes of the light emitting diodes or with increasing numbers of connected light emitting diodes, leading to a difficulty in manufacture itself.

As a second conventional light emitting device, as shown in FIG. 18, there is proposed a light emitting diode device 100 utilizing a semiconductor nanowire 114 (see Patent Literature 2: JP 2008-283191 A). This second conventional light emitting device 100 includes a semiconductor substrate 111, first and second semiconductor protruding portions 112, 113 placed opposite to each other on a top surface of the semiconductor substrate 111, and a semiconductor nanowire 114 stretched between the first semiconductor protruding portion 112 and the second semiconductor protruding portion 113. The second conventional light emitting diode device 100 further includes a first, second electrodes 115, 116 formed on top surfaces of the first, second semiconductor protruding portions 112, 113. The first semiconductor protruding portion 112 and part 114a of the semiconductor nanowire 114 extending from the first semiconductor protruding portion 112 are doped to p type, while the second semiconductor protruding portion 113 and part 114b of the semiconductor nanowire 114 extending from the second semiconductor protruding portion 113 are doped to n type.

With the second conventional light emitting diode device 100, if the P-doped part 114a and the N-doped part 114b of the semiconductor nanowire 114 are reversely connected to the first electrode 115 and the second electrode 116, it is no longer possible to obtain normal light emission. Accordingly, for the light emitting diode device 100, there is a need for uniformizing the polarity so as to prevent the reversal of connection of the p-type, n-type doped parts 114a, 114b in association with the first, second electrodes 115, 116 during the manufacturing process, so that simplification of the manufacturing process becomes difficult to achieve especially for smaller-sized light emitting diodes, incurring increases in the manufacturing cost.

### SUMMARY OF INVENTION

### Technical Problem

Accordingly, an object of the present invention is to provide a light emitting device, as well as a manufacturing method therefor, which includes a plurality of light emitting diodes capable of facilitating its manufacture and cutting down its manufacturing cost.

### Solution to Problem

In order to achieve the above object, the present invention provides a light emitting device comprising:

a first electrode;

a second electrode; and

a light emitting diode circuit which has at least one parallel structure unit composed of a plurality of light emitting diodes connected in parallel between the first electrode and the second electrode, and which is connected between the first electrode and the second electrode, wherein

the plurality of light emitting diodes making up the parallel structure unit comprise:

first light emitting diodes which are placed so as to be forward oriented when the first electrode is set higher in potential than the second electrode, and

second light emitting diodes which are placed so as to be forward oriented when the second electrode is set higher in potential than the first electrode, and wherein

in the parallel structure unit,

the first light emitting diodes and the second light emitting diodes are mixedly placed, and

the plurality of light emitting diodes are driven with an AC voltage applied to between the first electrode and the second electrode by AC power supply.

According to the light emitting device of this invention, since the plurality of light emitting diodes to be connected between the first, second electrodes do not need to be arrayed with their polarity uniformized, the step for uniformizing the polarity (orientation) of the plurality of light emitting diodes becomes unnecessary during the manufacture, thus allowing the manufacturing process to be simplified. Further, there is no need for providing marks on the light emitting diodes for discrimination of the polarity (orientation) of the light emitting diodes, and it also becomes unnecessary to form the light emitting diodes into any special shape for polarity discrimination. Therefore, the manufacturing process of the light emitting diodes can be simplified, and the manufacturing cost can also be cut down. In addition, for smaller sizes of the light emitting diodes or for larger numbers of light emitting diodes, the manufacturing process can be simplified to a considerable extent, compared with cases in which the light emitting diodes are arrayed with their polarity uniformized.

In an embodiment, the light emitting diode circuit is made up by series connection of a plurality of the parallel structure units.

According to the light emitting device of this embodiment, the step for uniformizing the polarity (orientation) of the light emitting diodes to be connected between the first electrode and the second electrode becomes unnecessary, allowing a process simplification to be achieved. Further, there is no need for providing marks on the light emitting diodes for discrimination of the polarity (orientation) of the light emitting diodes, and it also becomes unnecessary to form the light emitting diodes into any special shape for polarity discrimination. Therefore, according to the light emitting device of this embodiment, the manufacturing process of the light emitting diodes can be simplified, so that the manufacturing cost can be cut down. In particular, for smaller sizes of the light emitting diodes with their maximum size not more than 100 μm, the work for uniformizing the polarity (orientation) would become difficult to achieve because of the minute-sized component parts, in which case the manufacturing process of the embodiment can be simplified to a considerable extent, compared with cases in which the light emitting diodes are arrayed with their polarity uniformized.

Further in this embodiment, by virtue of the arrangement that a plurality of the parallel structure units are connected in series, even in a case where the light emitting diodes of one of the parallel structure units have come to no longer emit light, and not only one of those light emitting diodes, due to a short-circuit failure of one light emitting diode in one parallel structure unit, the light emitting diodes of the other parallel structure units are allowed to go on emitting light. Thus, the light emitting device of this embodiment is high in yield, allowing its reliability to be enhanced. Also according to the light emitting device of this embodiment, a planar light-emitting region can be obtained with ease.

In an embodiment, the light emitting diode circuit has a singularity of the parallel structure unit,

the first light emitting diode has

an anode connected to the first electrode and a cathode connected to the second electrode, and

the second light emitting diode has

a cathode connected to the first electrode and an anode connected to the second electrode.

According to the light emitting device of this embodiment, since the plurality of light emitting diodes to be connected between the first, second electrodes do not need to be arrayed with their polarity uniformized, the step for uniformizing the polarity (orientation) of the plurality of light emitting diodes becomes unnecessary during the manufacture, thus allowing the manufacturing process to be simplified. Further, there is no need for providing marks on the light emitting diodes for discrimination of the polarity (orientation) of the light emitting diodes, and it also becomes unnecessary to form the light emitting diodes into any special shape for polarity discrimination. Therefore, the manufacturing process of the light emitting diodes can be simplified, and the manufacturing cost can also be cut down. In addition, for smaller sizes of the light emitting diodes or for larger numbers of light emitting diodes, the manufacturing process can be simplified to a considerable extent, compared with cases in which the light emitting diodes are arrayed with their polarity uniformized.

In an embodiment, the plurality of parallel structure units are composed of a mutually equal number of light emitting diodes.

According to the light emitting device of this embodiment, amounts of currents flowing through the individual light emitting diodes can be equalized thereamong. As a result of this, it becomes possible that electric currents can be passed uniformly through the individual light emitting diodes, so that an efficient emission as a whole as well as high reliability can be obtained.

In an embodiment, the parallel structure unit is composed of m (m is a natural number of 2 or more) light emitting diodes,

a plurality n (n is a natural number of 2 or more) of the parallel structure units are connected in series to build the light emitting diode circuit, and

the number m and the number n satisfy a relationship that 1−(1−(½)^{m-1})ⁿ≦0.05.

According to the light emitting device of this embodiment, the percent defective for the whole light emitting diode circuit can be reduced to 5% or less.

This is explained below. First, a probability that all m light emitting diodes composing one parallel structure unit come into one identical orientation is (½)^{m-1}. This can be derived from properties of binomial distribution and a fact that there are two ways in which all the light emitting diodes are oriented identical (one case in which all are directed in one orientation, and another case in which all are directed in the other orientation). From this derivation, the probability that one parallel structure unit is kept from the aforementioned defective is 1−(½)^{m-1}. In a case of n-series connection of this parallel structure unit, since the probability that the light emitting diode circuit as a whole is kept from the above defective is (1−(½)^{m-1})ⁿ, the percent defective P as a whole of the light emitting diode circuit is expressed as P=1−(1−(½)^{m-1})ⁿ. Thus, satisfying a relationship between m and n as defined above that 1−(1−(½)^{m-1})ⁿ≦0.05 makes it possible to reduce the percent defective for the whole light emitting diode circuit to 5% or less.

In an embodiment, the number of the plural light emitting diodes is not less than 100 and not more than 100000000.

According to this embodiment, since the number of the light emitting diodes is 100 or more, flickers due to blinks occurring in AC drive can be suppressed.

That is, the plurality of light emitting diodes are oriented at random, and each light emitting diode has a probability of ½ for occurrence of each of one orientation and the other orientation. Hence, here is discussed a binomial distribution of p=0.5. Now, here is assumed that n light emitting diodes are present, where X diodes (X: a quantity number of light emitting diodes that emit light at a time) are positioned in one orientation. Then, from the properties of the binomial distribution, an expectation E(X) of X is expressed as E(X)=np, and variance V(X)=np(1−p). In addition, an index as to how X is deviated from its expectation, E(X)=np, is the square root of variance, {V(X)}^{1/2}, which is called standard deviation for cases of normal distribution. When this index (square root of variance) is 10% of the expectation, the followed equation (1) holds:

{np(1−p)}^{1/2}=0.1np (1)

Substituting p=0.5 in this Equation (1) and determining a solution for n results in n=100. This means that deriving a solution from conditions under which the variation of brightness is 10% of the expectation results in a quantity number of 100 of the light emitting diodes.

It is noted here that the upper-limit value (100000000) of the number of the light emitting diodes is a today's substantial manufacturing limit.

In an embodiment, AC frequency of the AC power supply is not less than 60 Hz and not more than 1 MHz.

According to this embodiment, since the AC frequency of the AC power supply is set to 60 Hz or more, flickers due to blinks of the light emitting diodes occurring in AC drive can be suppressed. Further, since the AC frequency of the AC power supply is set to 1 MHz or less, in-line losses due to high frequencies can be suppressed. AC frequencies of the AC power supply beyond 1 MHz leads to considerable in-line losses due to high frequencies.

In an embodiment, alternating current derived from the AC power supply is a rectangular wave.

According to this embodiment, since the light emitting diodes are driven by rectangular-wave AC, the light emitting diodes can be made to emit light at the most efficiency. For example, when light emitting diodes are driven with sinusoidal alternating current, the mean emission intensity is weakened by presence of leading- and tailing-edge slopes of the sinusoidal wave.

In an embodiment, the first electrode and the second electrode are formed on one substrate.

According to this embodiment, the first and the second electrodes and the plurality of light emitting diodes can be mounted on one substrate.

In an embodiment, the first electrode and the second electrode extend along a surface of the substrate and are opposed to each other,

the first electrode has a plurality of protruding portions which are formed so as to protrude toward the second electrode and be arrayed side by side along an extending direction of the first and second electrodes,

the second electrode has a plurality of protruding portions which are formed so as to protrude toward the first electrode and be arrayed side by side along the extending direction,

the protruding portions of the first electrode and the protruding portions of the second electrode are opposed to each other, and wherein

in the first light emitting diodes,

their anodes are connected to the protruding portions of the first electrode while their cathodes are connected to the protruding portions of the second electrode, and

in the second light emitting diodes,

their cathodes are connected to the protruding portions of the first electrode while their anodes are connected to the protruding portions of the second electrode.

According to this embodiment, since the plurality of light emitting diodes are connected between the protruding portions of the first, second electrodes along the extending direction of the first, second electrodes on the substrate, the plurality of light emitting diodes can be placed along the extending direction of the electrodes with the interval of the protruding portions. That is, placement of the plurality of light emitting diodes can be set by the first, second electrodes and their protruding portions formed on the substrate.

In an embodiment, a maximum size of the light emitting diodes is not more than 100 μm.

According to this embodiment, the maximum size of the light emitting diodes is not more than 100 μm. For placement of such minute-sized articles (light emitting diodes) with their orientation taken into consideration, it becomes necessary to prepare the minute-sized articles with their orientation uniformized. Or, it becomes necessary to do work of grasping minute-sized articles and then uniformizing their orientation. Therefore, cases of minute sizes of the light emitting diodes with their maximum size being 100 μm or less as in this embodiment are suitable for the present invention, in which the light emitting diodes may be oriented at random. Besides, since the light emitting diodes are small-sized, there occurs no heat accumulation in the emission regions, so that power decrease or life decrease due to heat can be prevented.

In an embodiment, the light emitting diodes are rod-like shaped.

According to this embodiment, since the light emitting diodes are rod-like shaped, control of their placement orientation is more easily achievable.

In an embodiment, a semiconductor layer forming the light emitting diodes is connected directly to the first, second electrodes.

According to this embodiment, there is no structure (e.g., lead wires longer on one side or the like) for orientation discrimination to uniformize the light emitting diodes into one orientation, the manufacturing process of the light emitting diodes can be simplified.

In an embodiment, the light emitting diodes each have

a first-conductive-type core portion, and

a second-conductive-type shell portion which covers an outer peripheral surface of the first-conductive-type core portion, where

part of the outer peripheral surface of the first-conductive-type core portion is exposed from the second-conductive-type shell portion.

According to this embodiment, the junction surface of the first-conductive-type core portion and the second-conductive-type shell portion can be formed along the outer peripheral surface of the core portion, allowing an increase in the light emission surface to be obtained. Also, since part of the outer peripheral surface of the core portion is exposed from the second-conductive-type shell portion, it becomes easier to connect the electrodes to part of the outer peripheral surface of the core portion.

In an embodiment, the core portion of each light emitting diode is columnar-shaped,

the shell portion of each light emitting diode covers the outer peripheral surface of the columnar-shaped core portion,

part of the outer peripheral surface of the columnar-shaped core portion is exposed from the shell portion, and

a junction surface between the columnar-shaped core portion and the shell portion is concentrically formed around the core portion.

According to this embodiment, the junction surface of the first-conductive-type columnar-shaped core portion and the second-conductive-type shell portion can be formed cylindrically along the outer peripheral surface of the core portion, allowing an increase in the light emission surface to be obtained. Also, since the part of the outer peripheral surface of the core portion is exposed from the second-conductive-type shell portion, it becomes easier to accomplish the connection of the electrodes to the part of the outer peripheral surface of the core portion.

A backlight for use in displays according to one embodiment of the invention includes the light emitting device as defined above. Therefore, its manufacture is easy to accomplish and the manufacturing cost can be cut down.

Also, an illuminating device according to one embodiment includes the light emitting device as defined above. Therefore, its manufacture is easy to accomplish and the manufacturing cost can be cut down.

Also, an LED display according to one embodiment includes the light emitting device as defined above. Therefore, its manufacture is easy to accomplish and the manufacturing cost can be cut down.

Also, a light emitting device manufacturing method according to one embodiment comprises the steps of:

preparing a substrate having a first electrode and a second electrode;

coating the substrate with a solution containing a plurality of light emitting diodes having a maximum size of 100 μm or less; and

applying a voltage to the first electrode and the second electrode to make the light emitting diodes arrayed into positions defined by the first, second electrodes.

According to the manufacturing method of this embodiment, the minute light emitting diodes can be placed at positions defined by the first, second electrodes by using the so-called dielectrophoresis. In this manufacturing method, it is difficult to determine orientation of the light emitting diodes into one orientation, thus the method being suitable for manufacturing the light emitting devices of the invention in which different orientations (polarities) of the light emitting diodes are mixed.

In another aspect of the present invention, there is provided a light emitting device comprising:

a first electrode formed on a substrate;

a second electrode formed on the substrate;

a third electrode formed on the substrate; and

a rod-like light emitting element which has a first-conductive-type first region, a second-conductive-type second region, and a first-conductive-type third region and in which the first region, the second region and the third region are placed in an order of the first region, the second region and the third region, wherein

the first region is connected to one of the first electrode and the third electrode, the second region is connected to the second electrode, and the third region is connected to the other of the first electrode and the third electrode.

According to the light emitting device of this invention, the first-conductive-type first region and the first-conductive-type third region are placed on both sides of the second-conductive-type second region of the rod-like light emitting element. Therefore, even if connection of the first, third regions of the rod-like light emitting element relative to the first, third electrodes is reversed, the diode polarity relative to the first third electrodes is not changed, so that it is possible to fulfill normal light emission. Therefore, the connection of the first, third regions relative to the first, third electrodes during the manufacturing process may be reversed, so that marks or shapes for discrimination of orientation of the rod-like light emitting element are no longer necessary, allowing a simplification of the manufacturing process as well as a cutdown of the manufacturing cost to be achieved.

In an embodiment, electric current is carried in either one of a first conductive direction and a second conductive direction, where the first conductive direction is a direction in which the electric current flows from one of the first electrode and the third electrode via sequentially the first region and the second region to the second electrode, and the second conductive direction is a direction in which the electric current flows from the second electrode via sequentially the second region and the first region to one of the first electrode and the third electrode, or electric current is carried in either one of a third conductive direction and a fourth conductive direction, where the third conductive direction is a direction in which the electric current flows from the other of the first electrode and the third electrode via sequentially the third region and the second region to the second electrode, and the fourth conductive direction is a direction in which the electric current flows from the second electrode via sequentially the second region and the third region to the other of the first electrode and the third electrode.

In an embodiment, electric current is carried in either one of a first conductive direction and a second conductive direction, where the first conductive direction is a direction in which the electric current flows from one of the first electrode and the third electrode via sequentially the first region and the second region to the second electrode and in which the electric current flows from the other of the first electrode and the third electrode via sequentially the third region and the second region to the second electrode, and the second conductive direction is a direction in which the electric current flows from the second electrode via sequentially the second region and the first region to one of the first electrode and the third electrode and moreover in which the electric current flows from the second electrode via sequentially the second region and the third region to the other of the first electrode and the third electrode.

In an embodiment, one end portion of the first region and the other end portion of the second region are joined together and moreover one end portion of the second region and the other end portion of the third region are joined together, and

the other end portion of the first region is connected to one of the first electrode and the third electrode, and moreover one end portion of the third region is connected to the other of the first electrode and the third electrode.

According to the light emitting device of this embodiment, the rod-like light emitting element can be formed into a rod-like shape in which the first, second, third regions are joined together in order, so that the rod-like light emitting element can be simplified in structure.

In an embodiment, the rod-like light emitting element comprises:

a core portion in which the first region and the third region adjoin each other in a rod-like shape and moreover extend through the second region; and

a shell portion which is formed of the second region and which covers an outer peripheral surface of the core portion, wherein

the first region and the third region of the core portion are exposed from both ends of the shell portion.

According to the light emitting device of this embodiment, the rod-like light emitting element has a light emitting surface given by a junction surface (p-n junction surface) between the outer peripheral surface of the core portion provided by the first-conductive-type first, third regions and the inner peripheral surface of the shell portion provided by the second-conductive-type second region. Therefore, a larger light emission area can be obtained, so that larger emission intensity can be obtained.

In an embodiment, a maximum size of the rod-like light emitting element is not more than 100 μm.

According to the light emitting device of this embodiment, the maximum size of the rod-like light emitting element is not more than 100 μm. For placement of the rod-like light emitting element, which is such a minute-sized article, with its orientation take into consideration, it becomes necessary to prepare the minute-sized rod-like light emitting elements with their orientation uniformized. Or, it becomes necessary to do work of grasping minute-sized rod-like light emitting elements and then uniformizing their orientation. Therefore, cases of minute sizes of the rod-like light emitting elements with their maximum size being 100 μm or less as in this embodiment are suitable for the present invention, in which the rod-like light emitting elements do not need to be uniformized in orientation. Besides, since the rod-like light emitting elements are sized as small as 100 μm or less, there occurs no heat accumulation in the emission regions, so that power decrease or life decrease due to heat can be prevented.

A backlight for use in displays according to one embodiment of the invention includes the light emitting device as defined above. Therefore, its manufacture is easy to accomplish and the manufacturing cost can be cut down.

Also, an illuminating device according to one embodiment includes the light emitting device as defined above. Therefore, its manufacture is easy to accomplish and the manufacturing cost can be cut down.

Also, an LED display according to one embodiment includes the light emitting device as defined above. Therefore, its manufacture is easy to accomplish and the manufacturing cost can be cut down.

Also in one embodiment, there is provided a manufacturing method for light emitting devices, comprising the steps of:

preparing a substrate having a first electrode, second electrode, and a third electrode;

coating the substrate with a solution containing a plurality of rod-like light emitting elements having a maximum size of 100 μm or less, the rod-like light emitting elements each having a first-conductive-type first region, a second-conductive-type second region, and a first-conductive-type third region, where the first region, the second region and the third region are placed in an order of the first region, the second region and the third region, and

applying a voltage to the first electrode and the third electrode to make the plurality of rod-like light emitting elements arrayed into positions defined by the first, second and third electrodes.

According to the light emitting device manufacturing method of this embodiment, the minute rod-like light emitting elements whose maximum size is 100 μm or less can be placed at positions defined by the first, second, third electrodes by using the so-called dielectrophoresis. In this manufacturing method, it is difficult to determine orientation of the rod-like light emitting elements into one orientation, thus the method being preferred as a light emitting device manufacturing method in which the rod-like light emitting elements do not need to be fixed in one orientation.

### ADVANTAGEOUS EFFECTS OF INVENTION

According to the light emitting device of this invention, since the plurality of light emitting diodes to be connected in parallel do not need to be arrayed with their polarity uniformized, the step for uniformizing the polarity (orientation) of the plurality of light emitting diodes becomes unnecessary during the manufacture, thus allowing the manufacturing process to be simplified. Further, since there is no need for providing marks on the light emitting diodes for discrimination of the polarity (orientation) of the light emitting diodes, it also becomes unnecessary to form the light emitting diodes into any special shape. Therefore, the manufacturing process of the light emitting diodes can be simplified, and the manufacturing cost can also be cut down.

According to the light emitting device of the invention, the first-conductive-type first region and the first-conductive-type third region are placed on both sides of the second-conductive-type second region of the rod-like light emitting element. Therefore, even if connection of the first, third regions of the rod-like light emitting element relative to the first, third electrodes is reversed, the diode polarity is not changed, so that it is possible to fulfill normal light emission. Therefore, the connection of the first, third regions relative to the first, third electrodes during the manufacturing process may be reversed, allowing a simplification of the manufacturing process as well as a cutdown of the manufacturing cost to be achieved.

### BRIEF DESCRIPTION OF DRAWINGS

The present invention will become more fully understood from the detailed description given hereinbelow and the accompanying drawings which are given by way of illustration only, and thus are not intended to limit the present invention, and wherein:

FIG. 1 is a view schematically showing an electric circuit structure of a first embodiment of a light emitting device according to the present invention;

FIG. 2 is a waveform diagram showing an example of AC waveform of an AC power supply for driving in this embodiment;

FIG. 3 is a circuit diagram showing an electric circuit structure of a second embodiment of the light emitting device of the invention;

FIG. 4 is a circuit diagram showing a modification of the embodiment;

FIG. 5 is a circuit diagram showing another modification of the embodiment;

FIG. 6 is a view showing percent defectives P relative to a number m of light emitting diodes connected in parallel in each parallel structure unit of the embodiment as well as to a number n of the parallel structure units connected in series;

FIG. 7 is a schematic plan view showing a third embodiment of the light emitting device according to the invention;

FIG. 8A is a perspective view showing one example of the structure of the light emitting diode of the embodiment;

FIG. 8B is an end face view of the light emitting diode;

FIG. 9A is a process view of a manufacturing method of a light emitting diode having a rod-like structure;

FIG. 9B is a process view of the manufacturing method of the rod-like structured light emitting element subsequent to FIG. 9A;

FIG. 9C is a process view of the manufacturing method of the rod-like structured light emitting element subsequent to FIG. 9B;

FIG. 9D is a process view of the manufacturing method of the rod-like structured light emitting element subsequent to FIG. 9C;

FIG. 9E is a process view of the manufacturing method of the rod-like structured light emitting element subsequent to FIG. 9D;

FIG. 10 is a view showing a circuit of one pixel of an LED (Light Emitting Diode) display as a fifth embodiment of the invention;

FIG. 11 is a plan view showing a sixth embodiment of the light emitting device according to the invention;

FIG. 12 is a plan view showing a seventh embodiment of the light emitting device according to the invention;

FIG. 13A is a side face view of a rod-like light emitting element included in the seventh embodiment;

FIG. 13B is a sectional view of the rod-like light emitting element;

FIG. 14 is a plan view showing a eighth embodiment of the light emitting device according to the invention;

FIG. 15A is a process view of the manufacturing method of the rod-like structured light emitting element subsequent to FIG. 9C;

FIG. 15B is a process view of the manufacturing method of the rod-like structured light emitting element subsequent to FIG. 15A;

FIG. 16 is a view showing a circuit of one pixel of an LED display as a tenth embodiment according to the invention;

FIG. 17 is a view showing a first conventional light emitting device; and

FIG. 18 is a perspective view showing a second conventional light emitting device.

### DESCRIPTION OF EMBODIMENTS

Hereinbelow, the present invention will be described in detail by way of embodiments thereof illustrated in the accompanying drawings.

### First Embodiment

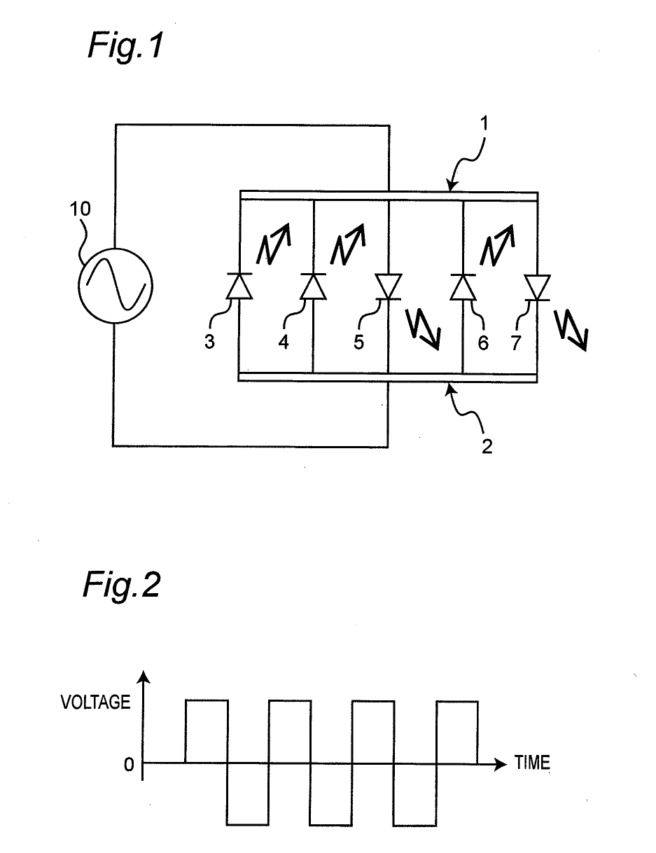

FIG. 1 schematically shows an electric circuit structure of a first embodiment of a light emitting device according to the present invention. The light emitting device of this first embodiment includes a first electrode 1 and a second electrode 2, and five light emitting diodes 3-7 connected in parallel between the first electrode 1 and the second electrode 2. The light emitting diodes 3, 4, 6 are each a second light emitting diode whose cathode is connected to the first electrode 1 and whose anode is connected to the second electrode 2. Meanwhile, the light emitting diodes 5, 7 are each a first light emitting diode whose anode is connected to the first electrode 1 and whose cathode is connected to the second electrode 2. An AC power supply 10 is connected to the first electrode 1 and the second electrode 2, and the AC power supply 10 applies AC voltage to the first electrode 1 and the second electrode 2. In this embodiment, the frequency of the AC voltage by the AC power supply 10 is set to 60 Hz. As shown in FIG. 1, the five light emitting diodes 3-7, i.e., the light emitting diodes 3, 4, 6 whose cathodes are connected to the first electrode 1 and the light emitting diodes 5, 7 whose cathodes are connected to the second electrode 2, are mixed and placed between the first electrode 1 and the second electrode 2. In this embodiment, out of the five light emitting diodes 3-7, three ones are connected in one orientation (with the cathode connected to the first electrode 1), while the remaining two are connected in the other orientation (with the cathode connected to the second electrode 2). However, the ratio of a number of light emitting diodes connected in one orientation to another number of light emitting diodes connected in the other orientation is not limited to this, and may be another ratio. That is, a number of light emitting diodes connected in one orientation and another number of light emitting diodes connected in the other orientation may be other than equal or near ones, and moreover may be other than constant in ratio. This means that the light emitting diodes do not need to be controlled for orientation but may be arrayed at random during the manufacture of the light emitting device of the invention. Whereas a considerably larger ratio of a number of light emitting diodes connected in one orientation to another number of light emitting diodes connected in the other orientation may cause flickers of light emission, methods for suppressing this occurrence will be described later.

According to the light emitting device of this embodiment, since the five light emitting diodes 3-7 to be connected in parallel between the first electrode 1 and the second electrode 2 do not need to be arrayed with their polarity uniformized, the step for uniformizing the polarity (orientation) of the five light emitting diodes 3-7 can be eliminated during the manufacture, thus allowing the manufacturing process to be simplified. Further, since there is no need for providing marks on the light emitting diodes 3-7 for discrimination of the polarity (orientation) of the light emitting diodes 3-7, it also becomes unnecessary to form the light emitting diodes 3-7 into any special shape for polarity discrimination.

Therefore, according to the light emitting device of this embodiment, the manufacturing process of the light emitting diodes 3-7 can be simplified, so that the manufacturing cost can be cut down. In particular, for smaller sizes of the light emitting diodes 3-7 with their maximum size not more than 100 μm, the work for uniformizing the polarity (orientation) becomes difficult to achieve because of the minute-sized component parts, in which case the manufacturing process can be simplified to a considerable extent, compared with cases in which the light emitting diodes are arrayed with their polarity uniformized.

The number of light emitting diodes to be connected between the first electrode 1 and the second electrode 2 is set to five in this embodiment. However, the number may also be set to five or less, or to six or more. For instance, when the number of light emitting diodes to be connected between the first electrode 1 and the second electrode 2 is set to 100 or more, flickers due to blinks occurring in AC drive can be suppressed, where variations of brightness can be suppressed to 10% or less of an expectation. This is explained below.

That is, the plurality of light emitting diodes are oriented at random, and each light emitting diode has a probability of ½ for occurrence of each of one orientation and the other orientation. Hence, here is discussed a binomial distribution of p=0.5. Now, here is assumed that n light emitting diodes are present, where X (a quantity number of light emitting diodes that emit light at a time) are positioned in one orientation. Then, from the properties of the binomial distribution, an expectation E(X) of X is expressed as E(X)=np, and variance V(X)=np(1−p). In addition, an index as to how X is deviated from its expectation, E(X)=np, is the square root of variance, {V(X)}^{1/2}, which is called standard deviation for cases of normal distribution. When this index (square root of variance) is 10% of the expectation, the followed equation (1) holds:

{np(1−p)}^{1/2}=0.1np (1)

Substituting p=0.5 in this Equation (1) and determining a solution for n results in n=100. This means that deriving a solution from conditions under which the variation of brightness is 10% of the expectation results in a quantity number of 100 of the light emitting diodes.

In addition, an upper-limit value of the number of light emitting diodes that can be connected between the first electrode 1 and the second electrode 2 is about 100000000 in terms of today's substantial manufacturing limits. Thus, for larger numbers of light emitting diodes to be connected between the first electrode 1 and the second electrode 2, the manufacturing process can be simplified to a considerable extent, compared with cases in which the light emitting diodes are arrayed with their polarity uniformized.

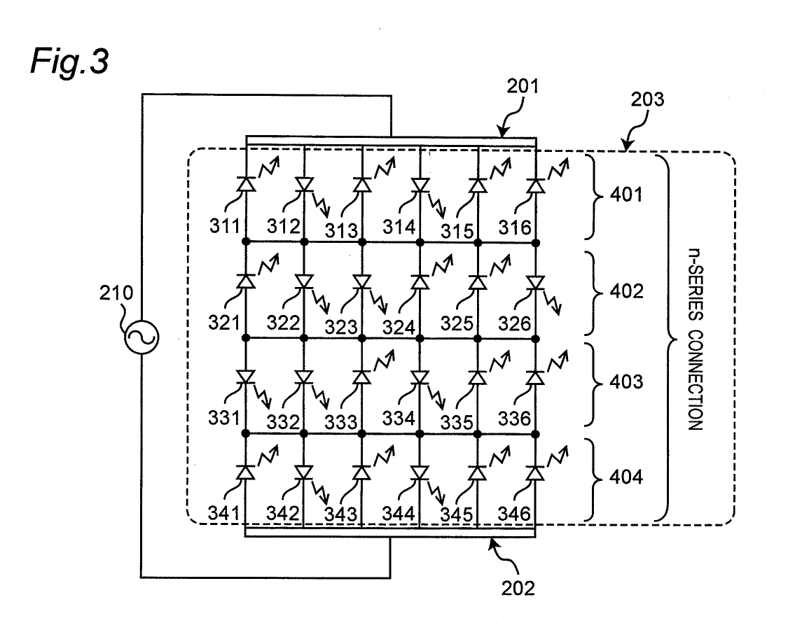

The frequency of AC voltage by the AC power supply 10 is set to 60 Hz in this embodiment. However, the frequency of the AC voltage may also be less than 60 Hz. This is true, but setting the frequency of the AC voltage to 60 Hz or more makes it possible to suppress the flickers due to blinks of the light emitting diodes occurring in AC drive. On the other hand, setting the frequency of the AC voltage to 1 MHz or less makes it possible to suppress in-line losses due to high frequencies. AC frequencies of the AC power supply beyond 1 MHz leads to considerable in-line losses due to high frequencies. Further, the waveform of the AC voltage may be sinusoidal wave, chopping wave, rectangular wave, or other periodically-changing AC waveform, but is desirably a rectangular wave. As an example, driving light emitting diodes with AC of such a rectangular wave as shown in FIG. 2 allows the light emitting diodes to emit light at the most efficiency. In contrast to this, when light emitting diodes are driven with sinusoidal alternating current, the mean emission intensity is weakened by presence of leading- and tailing-edge slopes of the sinusoidal wave.

Although the light emitting diodes 3-7 connected between the first electrode 1 and the second electrode 2 are connected directly to the AC power supply in FIG. 1, there may be another element or circuit between the light emitting diodes 3-7 and the AC power supply 10. For example, as far as AC voltage is applied to the light emitting diodes 3-7, there may be interposed a resistor, a capacitor, a diode, a transistor, or other elements, or a combinational circuit of these, between the light emitting diodes 3-7 and the AC power supply 10. Also, as far as AC voltage is applied to the light emitting diodes 3-7, there may be provided a resistor, a capacitor, a diode, a transistor, or other elements, or a combinational circuit of these, in parallel with the light emitting diodes 3-7.

In this embodiment, as shown in FIG. 1, the light emitting diodes 3, 4, 6 are connected in one orientation (with the cathode connected to the first electrode 1), while the light emitting diodes 5, 7 are connected in the other orientation (with the cathode connected to the second electrode 2). Therefore, as viewed from the light emitting diodes 3, 4, 6 connected in one orientation, the light emitting diodes 5, 7 connected in the other orientation serve as protective diodes. That is, even when a large reverse voltage due to a surge or the like is applied to the light emitting diodes 3, 4, 6 connected in one orientation, a forward current instantly flows through the light emitting diodes 5, 7 connected in the other orientation, giving rise to a voltage drop due to an unshown resistor in the AC power supply 10 or a resistor provided between the light emitting diodes and the power supply 10, so that application of large reverse voltages to the light emitting diodes 3, 4, 6 connected in one orientation can be prevented. Similarly, as viewed from the light emitting diodes 5, 7 connected in the other orientation, the light emitting diodes 3, 4, 6 connected in one orientation serve protective diode. That is, the light emitting diodes 3-7 fulfill not only functions as light emitting diodes but also functions as protective diodes. As a result, a light emitting device of high reliability can be obtained with less component parts.

### Second Embodiment

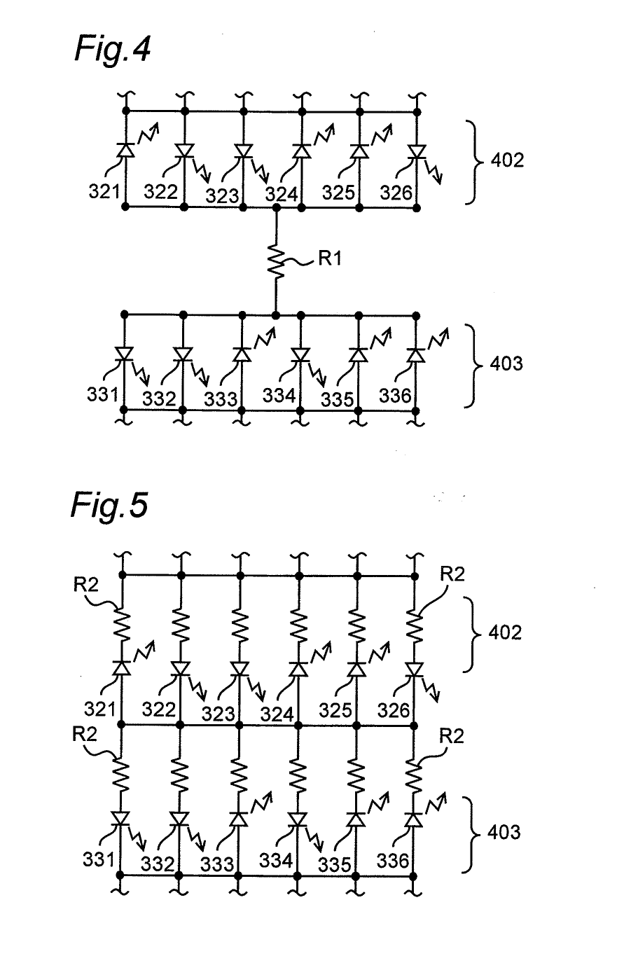

Next, a second embodiment of the light emitting device according to the invention will be described with reference to FIG. 3. FIG. 3 is a circuit diagram schematically showing an electric circuit structure of the second embodiment.

FIG. 3 schematically shows the electric circuit structure of the second embodiment of the light emitting device according to the invention. The light emitting device of this second embodiment includes a first electrode 201 and a second electrode 202, and a light emitting diode circuit 203 composed of twenty-four light emitting diodes 311-316, 321-326, 331-336, 341-346 connected in series and parallel between the first electrode 201 and the second electrode 202.

The six light emitting diodes 311-316 are connected in parallel to form a parallel structure unit 401. Likewise, the six light emitting diodes 321-326, the six light emitting diodes 331-336 and the six light emitting diodes 341-346 also form parallel structure units 402, 403, 404, respectively. These four parallel structure units 401-404 are connected in series to form the light emitting diode circuit 203, both ends of which are connected to the first electrode 201 and the second electrode 202.

In each of the parallel structure units 401-404, light emitting diodes connected in mutually opposed two orientations are mixedly included.

More specifically, in the parallel structure unit 401 composed of the light emitting diodes 311-316, cathodes of the light emitting diodes 311, 313, 315, 316 as second light emitting diodes are connected directly to the first electrode 201, while anodes of the light emitting diodes 311, 313, 315, 316 are connected to the second electrode 202 via the other parallel structure units 402-404. Also, anodes of the light emitting diodes 312, 314 as first light emitting diodes are connected directly to the first electrode 201, while cathodes of the light emitting diodes 312, 314 are connected to the second electrode 202 via the other parallel structure units 402-404. Also, in the parallel structure unit 402 composed of the light emitting diodes 321-326, cathodes of the light emitting diodes 321, 324, 325 as second light emitting diodes are connected to the first electrode 201 via another parallel structure unit 401, while anodes of the light emitting diodes 321, 324, 325 are connected to the second electrode 202 via the other parallel structure units 403, 404. Also, anodes of the light emitting diodes 322, 323, 326 as first light emitting diodes of the parallel structure unit 402 are connected to the first electrode 201 via another parallel structure unit 401, while cathodes of the light emitting diodes 322, 323, 326 are connected to the second electrode 202 via the other parallel structure units 403, 404.

Accordingly, in the parallel structure unit 401, the light emitting diodes 311, 313, 315, 316 as the second light emitting diodes are forward directed from the second electrode 202 toward the first electrode 201, while the light emitting diodes 312, 314 as the first light emitting diodes are forward directed from the first electrode 201 toward the second electrode 202. Also, in the parallel structure unit 402, the light emitting diodes 321, 324, 325 as the second light emitting diodes are forward directed from the second electrode 202 toward the first electrode 201, while the light emitting diodes 322, 323, 326 as the first light emitting diodes are forward directed from the first electrode 201 toward the second electrode 202.

Also, in the parallel structure unit 403, the light emitting diodes 333, 335, 336 as the second light emitting diodes are forward directed from the second electrode 202 toward the first electrode 201, while the light emitting diodes 331, 332, 334 as the first light emitting diodes are forward directed from the first electrode 201 toward the second electrode 202. Also, in the parallel structure unit 404, the light emitting diodes 341, 343, 345, 346 as the second light emitting diodes are forward directed from the second electrode 202 toward the first electrode 201, while the light emitting diodes 342, 344 as the first light emitting diodes are forward directed from the first electrode 201 toward the second electrode 202.

The AC power supply 210 is connected to the first electrode 201 and the second electrode 202, and the AC power supply 210 applies AC voltage to the first electrode 201 and the second electrode 202. In this embodiment, the frequency of the AC voltage by the AC power supply 210 is set to 60 Hz

As described above, the light emitting diodes forming each of the parallel structure units 401-404 mixedly include light emitting diodes connected in two orientations that are opposite to each other. The number of light emitting diodes connected in one orientation out of the two orientations and the number of light emitting diodes connected in the other orientation may be different ones, as shown in FIG. 3. This means that the light emitting diodes do not need to be controlled for orientation and may be arrayed at random during the manufacture of the light emitting device of the invention.

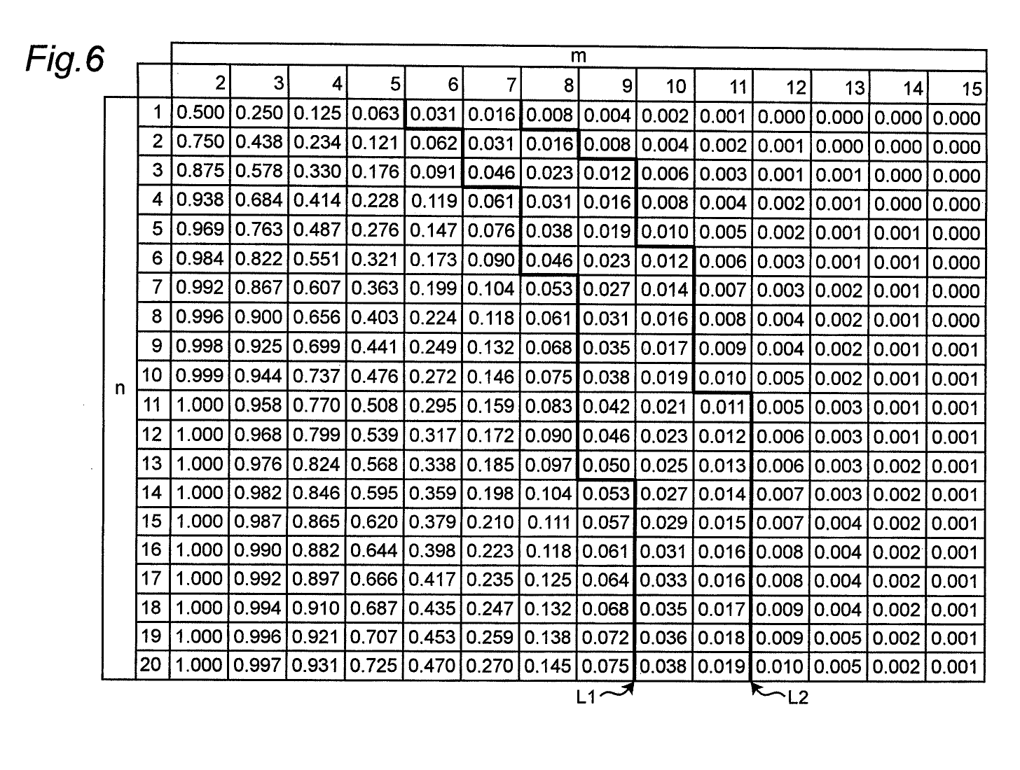

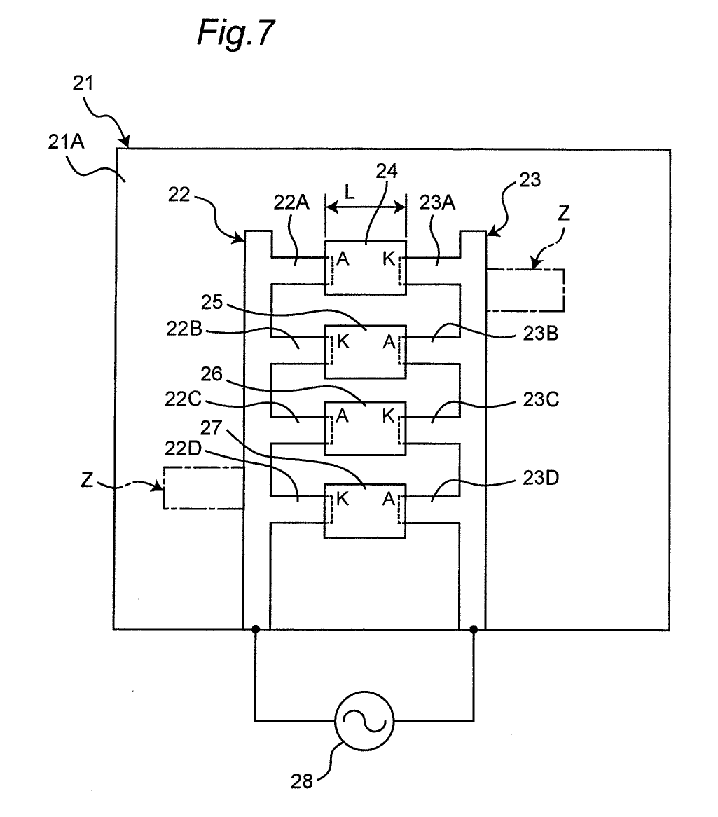

Also, the parallel structure units 401-404 connected in series between the first electrode 201 and the second electrode 202 are connected directly to the AC power supply 210 in FIG. 3. However, another element or circuit may be interposed between the series-connected parallel structure units and the AC power supply 210. For example, as far as AC voltage is applied to the series-connected parallel structure units 401-404, there may be interposed a resistor, a capacitor, a diode, a transistor, or other elements, or a combinational circuit of these, between the series-connected parallel structure units 401-404 and the AC power supply 210. Also, as far as AC voltage is applied to the series-connected parallel structure units 401-404, there may be provided a resistor, a capacitor, a diode, transistor, or other elements, or a combinational circuit of these, in parallel with the series-connected parallel structure units 401-404. Also, as far as AC voltage is applied to the parallel structure units 401-404, there may be interposed a resistor, a capacitor, a diode, a transistor, or other elements, or a combinational circuit of these, between the individual parallel structure units 401-404. For example, in one example shown in FIG. 4, a resistor R1 for current adjustment is connected between the parallel structure unit 402 and the parallel structure unit 403. Further, as far as AC voltage is applied to the individual light emitting diodes forming the parallel structure units 401-404, there may be provided a resistor, a capacitor, a diode, a transistor, or other elements, or a combinational circuit of these, within the parallel structure units 401-404. For example, in one example shown in FIG. 5, a resistor R2 for current adjustment is provided in series with the light emitting diodes 321-326, 331-336 forming the parallel structure unit 402, 403, respectively.

According to the light emitting device of this embodiment, the step for uniformizing the polarity (orientation) of the light emitting diodes to be connected between the first electrode 201 and the second electrode 202 becomes unnecessary, allowing a process simplification to be achieved. Further, since there is no need for providing marks on the light emitting diodes for discrimination of the polarity (orientation) of the light emitting diodes, it also becomes unnecessary to form the light emitting diodes into any special shape for polarity discrimination.

Therefore, according to the light emitting device of this embodiment, the manufacturing process of the light emitting diodes can be simplified, so that the manufacturing cost can be cut down. In particular, for smaller sizes of the light emitting diodes with their maximum size not more than 100 μm, the work for uniformizing the polarity (orientation) becomes difficult to achieve because of the minute-sized component parts, in which case the manufacturing process can be simplified to a considerable extent, compared with cases in which the light emitting diodes are arrayed with their polarity uniformized.

In this embodiment, light emitting diodes connected in one orientation and light emitting diodes connected in the other orientation are mixedly included in each of the parallel structure units 401-404, as shown in FIG. 3. In this respect, a plurality of light emitting diodes forming one parallel structure unit 401, 402, 403, 404 are similar to the light emitting diodes 3-7 of the foregoing first embodiment (see FIG. 1). Therefore, this second embodiment can be said to be an embodiment in which the light emitting diodes 3-7 of the foregoing first embodiment are arranged in multiple stages.

Therefore, also applicable to this second embodiment is the characteristic, as described in the above first embodiment, that the light emitting diodes connected in the other orientation serve as protective diodes as viewed from the light emitting diodes connected in one orientation, while the light emitting diodes connected in one orientation serve as protective diodes as viewed from the light emitting diodes connected in the other orientation. Thus, also in this second embodiment, the light emitting diodes fulfill not only functions as light emitting diodes but also functions as protective diodes. As a result, a light emitting device of high reliability can be obtained with less component parts.

Furthermore, the light emitting device of this second embodiment has an advantage of being strong to short-circuit failures, compared with the light emitting device of the above first embodiment. For example, upon occurrence of a short-circuit failure in any one of the light emitting diodes 3-7 (see FIG. 1) of the above first embodiment, the light emitting diodes no longer emit light, nor does even only one of the light emitting diodes. Meanwhile, in this second embodiment, upon occurrence of a short-circuit failure of the light emitting diode 311 in FIG. 3 as an example, the light emitting diodes 311-316 of the parallel structure unit 401 come not to emit light, but the light emitting diodes of the other parallel structure units 402-404 are allowed to go on emitting light. Thus, the light emitting device of this second embodiment is high in yield, allowing its reliability to be enhanced.

In addition, although the number of light emitting diodes forming each of the parallel structure units 401-404 is a fixed number (six) in all cases in the second embodiment, but this is not limitative. That is, the number of light emitting diodes forming each parallel structure unit may be more than or less than six, and may be 100 or more as an example. Also, the number of light emitting diodes forming each parallel structure unit may be varied among the individual parallel structure units. For example, it is allowable that the parallel structure unit 401 is composed of six light emitting diodes, the parallel structure unit 402 is composed of five light emitting diodes, and the parallel structure units 403 and 404 are each composed of seven light emitting diodes. However, the number of light emitting diodes forming each of the parallel structure units 401-404 is preferably set equal to one another, as shown in FIG. 3. As the reason of this, since the parallel structure units 401-404 are connected in series, the total amount of currents flowing through each of the parallel structure units 401-404 is equal among those parallel structure units, so that equalizing the number of light emitting diodes forming each of the parallel structure units 401-404 makes it possible to equalize the amount of currents flowing through the individual light emitting diodes. As a result of this, it becomes possible that electric currents can be passed uniformly through the individual light emitting diodes, so that an efficient emission as a whole as well as high reliability can be obtained.

In execution of the second embodiment, the step for uniformizing the polarity (orientation) of the light emitting diodes to be connected between the first electrode 201 and the second electrode 202 is omitted. Therefore, in cases where orientation of light emitting diodes is determined contingently, there may occur a failure that the light emitting diodes forming one parallel structure unit 401-404 are positioned contingently all in one orientation. In this state, with alternating current applied to the first, second electrodes 201, 202, the defective parallel structure unit does not conduct the electric current therethrough in half periods, so that all the light emitting diodes are extinguished in these half periods. Here is considered a percent defective in a case where each parallel structure unit is composed of m light emitting diodes, equal in number for every parallel structure unit, and a plurality n of the parallel structure units are connected in series.

First, a probability that all m light emitting diodes composing one parallel structure unit come into one identical orientation (polarity) is (½)^{m-1}. This can be derived from properties of binomial distribution and a fact that there are two ways in which all the light emitting diodes are oriented identical (one case in which all are directed in one orientation, and another case in which all are directed in the other orientation). From this derivation, the probability that one parallel structure unit is kept from the aforementioned defective is 1−(½)^{m-1}. In a case of n-series connection of this parallel structure unit, since the probability that the light emitting diode circuit as a whole is kept from the above defective is (1−(½)^{m-1})ⁿ, the percent defective P as a whole of the light emitting diode circuit is expressed as P=1−(1−(½)^{m-1})ⁿ.

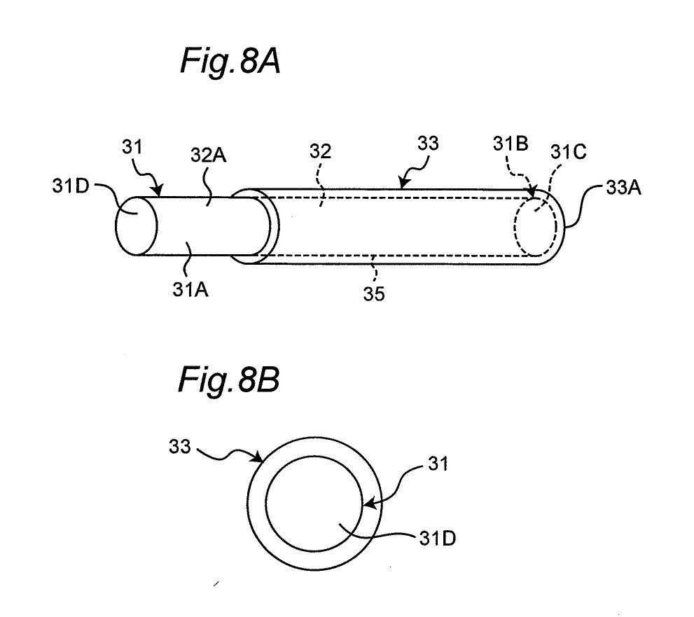

Described in a table shown in FIG. 6 are percent defectives P in association with the number m of light emitting diodes connected in parallel in each parallel structure unit as well as the number n of the parallel structure units connected in series. From this table, for example, in a case where the parallel connection number m=9, it can be found that the percent defective is 1% or less with the series connection number n equal to 2 or less, while the percent defective is 5% or less with n equal to 13 or less. From the viewpoint of mass production, it is preferable that P is 0.05 (5%) or less, i.e., a relationship that 1−(1−(½)^{m-1})ⁿ≦0.05 is satisfied (right-hand zone of thick line L1 in the table of FIG. 6), and more preferable that P is 0.01 (1%) or less (right-hand zone of thick line L2 in the table of FIG. 6).

In addition, the upper-limit value of the number of light emitting diodes that can be connected between the first electrode 201 and the second electrode 202 is about 100000000 in terms of today's substantial manufacturing limits. For larger numbers of light emitting diodes connected between the first electrode 201 and the second electrode 202 as shown above, the manufacturing process can be simplified to a considerable extent, compared with cases in which the light emitting diodes are arrayed with their polarity uniformized.

The frequency of AC voltage by the AC power supply 210 is set to 60 Hz in this embodiment. However, the frequency of the AC voltage may also be less than 60 Hz. This is true, but setting the frequency of the AC voltage to 60 Hz or more makes it possible to suppress the flickers due to blinks of the light emitting diodes occurring in AC drive. On the other hand, setting the frequency of the AC voltage to 1 MHz or less makes it possible to suppress in-line losses due to high frequencies. AC frequencies of the AC power supply beyond 1 MHz leads to considerable in-line losses due to high frequencies. Further, the waveform of the AC voltage may be sinusoidal wave, chopping wave, rectangular wave, or other periodically-changing AC waveform, but is desirably a rectangular wave. As an example, driving light emitting diodes with AC of such a rectangular wave as shown in FIG. 2 allows the light emitting diodes to emit light at the most efficiency. In contrast to this, when light emitting diodes are driven with sinusoidal alternating current, the mean emission intensity is weakened by presence of leading- and tailing-edge slopes of the sinusoidal wave.

### Third Embodiment

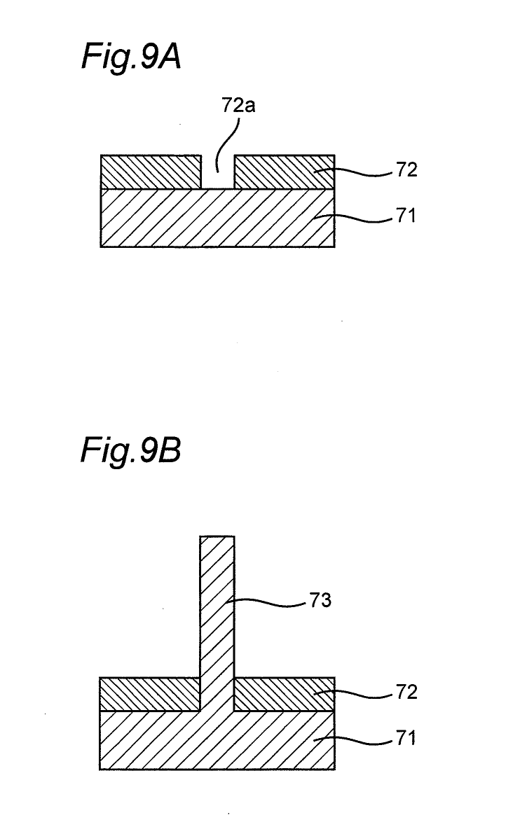

Next, a third embodiment of the light emitting device according to the invention will be described with reference to FIG. 7. FIG. 7 is a schematic plan view showing the third embodiment.

The light emitting device of this third embodiment includes a substrate 21, a first electrode 22 formed on the substrate 21, a second electrode 23 formed on the substrate 21, and four light emitting diodes 24, 25, 26, 27. These first electrode 22 and the second electrode 23 extend generally parallel to each other along a surface 21A of the substrate 21 and are opposed to each other. The first electrode 22 has four protruding portions 22A, 22B, 22C, 22D which are positioned in parallel to one another with a certain interval along the extending direction of the first electrode 22 and which protrude toward the second electrode 23. Also, the second electrode 23 has four protruding portions 23A, 23B, 23C, 23D which are positioned in parallel to one another with a certain interval along the extending direction of the second electrode 23 and which protrude toward the first electrode 22. The four protruding portions 22A, 22B, 22C, 22D of the first electrode 22 are opposed to the four protruding portions 23A, 23B, 23C, 23D of the second electrode 23, respectively.

In the example shown in FIG. 7, the light emitting diodes 24, 26 as the first light emitting diodes have their anodes A connected to the protruding portions 22A, 22C of the first electrode 22, and their cathodes K connected to the protruding portions 23A, 23C of the second electrode 23. Also, the light emitting diodes 25, 27 as the second light emitting diodes have their cathodes K connected to the protruding portions 22B, 22D of the first electrode 22, and their anodes A connected to the protruding portions 23B, 23D of the second electrode 23. In this embodiment, the light emitting diodes 24-27 are formed into a rod-like shape with a length L of 10 μm, as an example.

An AC power supply 28 is connected to the first electrode 22 and the second electrode 23. In this embodiment, the AC frequency of the AC power supply 28 is set to 60 Hz. As to the four light emitting diodes 24-27, as shown in FIG. 7, the light emitting diodes 24, 26 having the anodes A connected to the first electrode 22, and the light emitting diodes 25, 27 having the anodes A connected to the second electrode 23, are mixedly placed between the first electrode 22 and the second electrode 23. In addition, in the one example shown in FIG. 7, the light emitting diodes 24, 26 having the anodes A connected to the first electrode 22, and the light emitting diodes 25, 27 having the anodes A connected to the second electrode 23, are alternately arrayed. Alternatively, the light emitting diodes 26 and 27 may be replaced with each other. That is, it is allowable that the light emitting diode 25 having the cathode K connected to the protruding portion 22B of the first electrode 22 and the light emitting diode 27 having the cathode K connected to the protruding portion 22C of the first electrode 22 are arrayed between the light emitting diode 24 having the anode A connected to the protruding portion 22A of the first electrode 22 and the light emitting diode 26 having the anode A connected to the protruding portion 22D of the first electrode 24. Also, the ratio of the number of light emitting diodes connected in one orientation (with the cathode connected to the first electrode 22) to the number of light emitting diodes connected in the other orientation (with the cathode connected to the second electrode 23) is not limited to this, and may be another one. That is, the number of light emitting diodes connected in one orientation and the number of light emitting diodes connected in the other orientation may be other than equal to each other, and moreover other than constant in their ratio. This means that the light emitting diodes do not need to be controlled for orientation but may be arrayed at random during the manufacture of the light emitting device of the invention. Whereas a considerably larger ratio of the number of light emitting diodes connected in one orientation to the number of light emitting diodes connected in the other orientation may cause flickers of light emission, methods for suppressing this occurrence will be described later.

According to the light emitting device of this embodiment, the four light emitting diodes 24-27 to be connected in parallel between the first electrode 22 and the second electrode 23 do not need to be arrayed with their polarity uniformized, so that the step for uniformizing the polarity (orientation) of the four light emitting diodes 24-27 is no longer necessary during the manufacture, thus allowing a process simplification to be achieved. Further, since there is no need for providing marks on the light emitting diodes 24-27 for discrimination of the polarity (orientation) of the light emitting diodes 24-27, it also becomes unnecessary to form the light emitting diodes 24-27 into any special shape for polarity discrimination. Therefore, according to the light emitting device of this embodiment, the manufacturing process of the light emitting diodes 24-27 can be simplified, so that the manufacturing cost can also be cut down. In particular, for smaller sizes of the light emitting diodes 24-27 with their maximum size not more than 100 μm, being equal to 10 μm, the work for uniformizing the polarity becomes difficult to achieve because of the minute-sized component parts, in which case the manufacturing process can be simplified to a considerable extent, compared with cases in which the light emitting diodes are arrayed with their polarity uniformized. It is noted that the maximum size of the light emitting diodes 24-27 may be less than 10 μm or beyond 10 μm.

Also according to this embodiment, the first, second electrodes 22, 23 and the four light emitting diodes 24-27 can be mounted on the substrate 21, and the light emitting diodes 24-27 are connected between the protruding portions 22A-22D and 23A-23D of the first, second electrodes 22, 23 placed on the substrate 21 with a certain interval along the extending direction of the first, second electrodes 22, 23. Therefore, the four light emitting diodes 24-27 can be arrayed in line along the extending direction of the electrodes 22, 23. That is, placement of the four light emitting diodes can be set by the first, second electrodes 22, 23 and their protruding portions 22A-22D, 23A-23D formed on the substrate 21. Moreover, since the light emitting diodes 24-27 are rod-like shaped in this embodiment, it becomes easier to control their placement orientation toward the protruding direction of the individual protruding portions between the protruding portions 22A-22D of the first electrode 22 and the protruding portions 23A-23D of the second electrode 23.

The number of light emitting diodes connected between the first electrode 22 and the second electrode 23 is set to four in this embodiment, but may be less than 4 or not less than 5. For example, when the number of light emitting diodes to be connected between the first electrode and the second electrode 23 is set to 100 or more, flickers due to blinks occurring in AC drive can be suppressed, where variations of brightness can be suppressed to 10% or less of an expectation. This is explained below.

That is, the plurality of light emitting diodes are oriented at random, and each light emitting diode has a probability of ½ for occurrence of each of one orientation and the other orientation. Hence, here is discussed a binomial distribution of p=0.5. Now, here is assumed that n light emitting diodes are present, where X (a quantity number of light emitting diodes that emit light at a time) are positioned in one orientation. Then, from the properties of the binomial distribution, an expectation E(X) of X is expressed as E(X)=np, and variance V(X)=np(1−p). In addition, an index as to how X is deviated from its expectation, E(X)=np, is the square root of variance, {V(X)}^{1/2}, which is called standard deviation for cases of normal distribution. When this index (square root of variance) is 10% of the expectation, the followed equation (1) holds:

{np(1−p)}^{1/2}=0.1np (1)

Substituting p=0.5 in this Equation (1) and determining a solution for n results in n=100. This means that deriving a solution from conditions under which the variation of brightness is 10% of the expectation results in a quantity number of 100 of the light emitting diodes.

In addition, the upper-limit value of the number of light emitting diodes that can be connected between the first electrode 22 and the second electrode 23 is about 100000000 in terms of today's substantial manufacturing limits. Thus, for larger numbers of light emitting diodes to be connected between the first electrode 22 and the second electrode 23, the manufacturing process can be simplified to a considerable extent, compared with cases in which the light emitting diodes are arrayed with their polarity uniformized. Also, the frequency of AC voltage by the AC power supply 28 is set to 60 Hz in this embodiment. However, the frequency of the AC voltage may also be less than 60 Hz. This is true, but setting the frequency of the AC voltage to 60 Hz or more makes it possible to suppress the flickers due to blinks of the light emitting diodes occurring in AC drive. On the other hand, setting the frequency of the AC voltage to 1 MHz or less makes it possible to suppress in-line losses due to high frequencies. Further, the waveform of the AC voltage may be sinusoidal wave, chopping wave, rectangular wave, or other waveform, but is desirably a rectangular wave. As an example, driving light emitting diodes with AC of such a rectangular wave as shown in FIG. 2 allows the light emitting diodes to emit light at the most efficiency. Further, the p-type semiconductor layer and the n-type semiconductor layer forming the light emitting diodes 24-27 are preferably connected directly to the protruding portions 22A-22D, 23A-23D of the first, second electrodes 22, electrode 23. As a result of this, there is provided a structure free from lead wire or the like for connecting the light emitting diodes 24-27 to the electrodes 22, 23 with their polarity uniformized, preferable for this embodiment that has no need for uniformizing the polarity of the light emitting diodes.

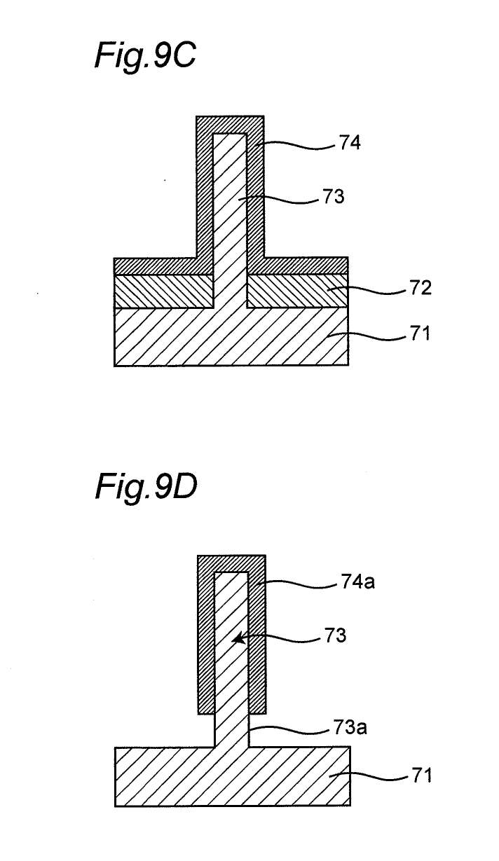

For example, as shown in FIG. 8A, the light emitting diode 24-27 may be composed of a columnar-shaped core portion 31 made of n-type semiconductor, and a cylindrical-shaped shell portion 33 made of p-type semiconductor that covers an outer peripheral surface 32 of the core portion 31. It is noted that FIG. 8B is an end face view of the light emitting diode as viewed from the end face 31D side of the columnar-shaped core portion 31 in the axial direction. A part 32A of the outer peripheral surface 32 of the columnar-shaped core portion 31 is exposed from the shell portion 33. Also, a junction surface 35 between the columnar-shaped core portion 31 and the shell portion 33 is formed concentrically around the columnar-shaped core portion 31. The portion 31A of the core portion 31 exposed from the shell portion 33 forms the cathode K, and an end portion 33A of the shell portion 33 forms an anode A. Then, the cathode K or the anode A is directly connected to one of the protruding portions 22A-22D and the protruding portions 23A-23D of the first, second electrodes 22, 23. In the light emitting diode of the construction shown in FIGS. 8A and 8B, the junction surface 35 between the n-type columnar-shaped core portion 31 and the p-type shell portion 33 can be formed cylindrically along the outer peripheral surface 32 of the core portion 31, allowing an increase in the light emission surface to be obtained. Also, since the part 32A of the outer peripheral surface 32 of the core portion 31 is exposed from the p-type shell portion 33, it becomes easier to accomplish the connection of the electrodes 22, 23 to the part 32A of the outer peripheral surface 32 of the core portion 31.

In addition, an end face 31C of one end 31B of the core portion 31 may be exposed from the end portion 33A of the shell portion 33. However, in a case where the end portion 33A of the shell portion 33 covers the end face 31C of the one end 31B of the core portion 31, it becomes easier to accomplish the connection of the end portion 33A of the shell portion 33 to the protruding portions of the first, second electrodes 22, 23. It is also possible that the semiconductor to form the shell portion 33 is the n-type one while the semiconductor to form the core portion 31 is the p-type one. Further, the core portion 31 is columnar-shaped and the shell portion 33 is cylindrical-shaped in the case of FIGS. 8A and 8B, but they may be provided as a polygonal prism-shaped core portion and a polygonal cylinder-shaped shell portion. For example, those portions may be a hexagonal prism-shaped core portion and a hexagonal cylinder-shaped shell portion, or a quadrangular prism-shaped core portion and a quadrangular cylinder-shaped shell portion, or a triangular prism-shaped core portion and a triangular cylinder-shaped shell portion. Besides, those portions may be an elliptic column-shaped core portion and an elliptic cylinder-shaped shell portion.

### Fourth Embodiment

Next, a manufacturing method of light emitting devices will be described as a fourth embodiment of the invention. In this fourth embodiment, a method for manufacturing such a light emitting device as described in the foregoing third embodiment will be explained with reference to FIG. 7.

In the fourth embodiment, first, a substrate 21 having a first electrode 22 and a second electrode 23 formed on its surface 21A is prepared. This substrate 21 is an insulating substrate, and the first, second electrodes 22, 23 are metal electrodes. As an example, metal electrodes 22, 23 of desired electrode shape may be formed on the surface 21A of the insulating substrate 21 by utilizing printing techniques. It is also possible that with a metal film and a photoreceptor film stacked uniformly on the surface 21A of the insulating substrate 21, the photoreceptor film is subjected to exposure and development of a desired electrode pattern, and then with the patterned photoreceptor film used as a mask, the metal film is etched, by which the first electrode 22 and the second electrode 23 can be formed.

Usable as the metal material for forming the metal electrodes 22, 23 are gold, silver, copper, iron, tungsten, tungsten nitride, aluminum, tantalum, alloys of these metals, and the like. Also, the insulating substrate 21 is made of such an insulator as glass, ceramic, alumina or resin, or such a semiconductor as silicon on a surface of which silicon oxide is formed so that the surface has insulative property. When a glass substrate is used, a ground insulative film such as silicon oxide or silicon nitride is formed on a surface of the glass substrate, desirably.

The distance between the protruding portion 22A of the first electrode 22 and the protruding portion 23A of the second electrode 23 is, preferably, slightly shorten than the length of the light emitting diodes 24-27. As an example, the distance is desirably 6 to 9 μm when the length of the light emitting diodes 24-27 is 10 μm. That is, the distance is desirably about 60 to 90% of the length of the light emitting diodes 24-27, more preferably, 80 to 90% of the length. The distance between the protruding portions 22B, 22C, 22D of the first electrode 22 and the protruding portions 23B, 23C, 23D of the second electrode 23 is also the same as the distance between the protruding portion 22A and the protruding portion 23A.

Next, the procedure for arraying the light emitting diodes 24-27 on the insulating substrate 21 will be explained. First, isopropyl alcohol (IPA) as a solution containing the light emitting diodes 24-27 is thinly applied on the insulating substrate 21. Other than IPA, usable as the solution are ethylene glycol, propylene glycol, methanol, ethanol, acetone, or mixtures of those materials, as well as liquids formed from other organic matters, water or the like. However, when a large current flows through the liquid between the metal electrodes 22, 23, a desired potential difference can no longer be applied to between the metal electrodes 22, 23. In such a case, the overall surface of the insulating substrate 21 may properly be coated with an insulative film of about 10 nm to 30 nm so as to make the metal electrodes 22, 23 covered therewith.

A thickness to which the IPA containing the light emitting diodes 24-27 is applied is such that the light emitting diodes 24-27 is movable in the liquid so that the light emitting diodes 24-27 can be arrayed in the step of subsequently arraying the light emitting diodes 24-27. Accordingly, the thickness is equal to or more than the thickness of the light emitting diodes 24-27, e.g., several μm to several mm. Too small thicknesses of application would cause difficulty for the light emitting diodes 24-27 to move, while too large thicknesses would cause the time of drying the liquid to be elongated. Preferably, the thickness is 100 μm to 500 μm. Also, the number of light emitting diodes relative to the quantity of IPA is preferably 1×10⁴/cm³ to 1×10⁷/cm³.

For application of IPA containing the light emitting diodes 24-27 onto the insulating substrate 21, it is appropriate that a frame (not shown) is formed on outer peripheries of the metal electrodes 22, 23 for array of the light emitting diodes 24-27, and IPA containing the light emitting diodes 24-27 is filled inside the frame to a desired thickness. However, when the IPA containing the light emitting diodes 24-27 has viscosity, it is implementable to achieve application of a desired thickness without the need for the frame. Liquids such as the IPA or ethylene glycol, propylene glycol, methanol, ethanol, acetone or mixtures of those, or liquids formed from other organic matters, or water or other liquid are desirably as low in viscosity as possible in terms of the step of arraying the light emitting diodes 24-27, and also desirably easy to evaporate by heating.

Next, a potential difference is given to between the metal electrodes 22, 23. This potential difference is set to 0.5 V or 1 V, as an example. As this potential difference between the metal electrodes 22 and 23, a potential difference of 0.1-10 V may be applied, where potential differences of 0.1 V or less would cause the light emitting diodes 24-27 to come to be disarrayed in posture, while potential differences of 10 V or more give rise to a problem of insulation between the metal electrodes. Accordingly, the potential difference is preferably set to 0.5 V-5 V, more preferably to about 0.5 V. When a potential VL is given to the metal electrode 22 while a potential VH (VL<VH) higher than the potential VL is given to the metal electrode 23, negative charge is induced to the metal electrode 22 while positive charge is induced to the metal electrode 23. With the light emitting diodes 24-27 approaching the metal electrodes 22, 23, positive charge is induced to one side of the light emitting diodes 24-27 closer to the metal electrode 22, while negative charge is induced to the other side closer to the metal electrode 23. The induction of electric charge to the light emitting diodes 24-27 is due to electrostatic induction. Therefore, the light emitting diodes 24-27 are postured along lines of electric force occurring between the metal electrodes 22, 23, and moreover because of nearly equal charge being induced to the light emitting diodes 24-27, the light emitting diodes 24-27 are arrayed regularly with nearly equal intervals in a certain direction by the repulsive force due to the electric charge. In this case, assuming that the surfaces of the metal electrodes 22, 23 are coated with insulative film and moreover that the potential difference given to between the metal electrodes 22, 23 is constant (DC), ions of an opposite polarity to the potential of the metal electrodes 22, 23 are induced to the surfaces of the coated insulative film on the metal electrodes 22, 23, so that the electric field in the solution becomes considerably weakened. In such a case, it is preferable that AC voltage is applied to between the metal electrodes 22, 23. As a result of this, the induction of ions of an opposite polarity to the potential of the metal electrodes 22, 23 can be prevented, so that the light emitting diodes 24-27 can be arrayed normally. In addition, frequency of the AC voltage applied to between the metal electrodes 22, 23 is preferably 10 Hz to 1 MHz. However, when the frequency of the AC voltage is less than 10 Hz, there is a possibility that the light emitting diodes 24-27 vibrate heavily so as to be disarrayed. On the other hand, when the frequency of the AC voltage applied to between the metal electrodes 22, 23 is beyond 1 MHz, the force with which the light emitting diodes 24-27 are sucked up to the metal electrodes 22, 23 is weakened, so that the light emitting diodes 24-27 are disarrayed by external disturbance. Therefore, for stabilized array of the light emitting diodes 24-27, it is more preferable that the frequency of the AC voltage is set to 50 Hz-1 kHz. Moreover, the waveform of the AC voltage, without being limited to sinusoidal wave, may be any one of rectangular wave, chopping wave, sawtooth wave or the like, whichever it varies periodically. In addition, the amplitude of the AC voltage is preferably set to about 0.5 V as an example.

As shown above, in this embodiment, since electric charge is generated to the light emitting diodes 24-27 by external electric field generated between the metal electrodes 22, 23, so that the light emitting diodes 24-27 are sucked up to the metal electrodes 22, 23 by attractive force of the electric charge. Therefore, it is necessary that the light emitting diodes 24-27 be sized movable in liquid. Accordingly, the permissible value of the size (maximum size) of the light emitting diodes 24-27 varies depending on the amount of liquid application (application thickness). The size (maximum size) of the light emitting diodes 24-27 has to be on the nano-scale for smaller amounts of liquid application, but the size of each light emitting diode 24-27 may be on the micron order for larger amounts of liquid application.

Soon after the beginning of the array of the light emitting diodes 24-27, the light emitting diodes 24-27 are arrayed between the protruding portion 22A-22D of the electrode 22 and the protruding portions 23A-23D of the electrode 23 as schematically shown in FIG. 7. The light emitting diodes 24-27 are arrayed in a posture vertical to the extending direction of the metal electrodes 22, 23 so as to be arrayed at generally equal intervals in the extending direction. Electric fields are concentrated between the protruding portions 22A-22D and the protruding portions 23A-23D, and moreover repulsive force acts between the light emitting diodes 24-27 by electric charge induced to the light emitting diodes 24-27, so that the light emitting diodes 24-27 are arrayed at generally equal intervals.

In addition, as shown by imaginary line in FIG. 7, light emitting diodes Z which are contained in the solution but not included in the light emitting diodes 24-27 may be sucked to the electrode 22 or the electrode 23. In this case, the solution of IPA or the like is passed to around the electrodes 22, 23 with the AC voltage kept applied to between the electrodes 22, 23, by which the light emitting diodes Z sucked to the electrode 22 or the electrode 23 can be removed. Thus, improvement of the yield can be achieved.

After the light emitting diodes 24-27 are arrayed between the protruding portions 22A-22D and the protruding portions 23A-23D of the metal electrodes 22, 23 in the way described above, the substrate 21 is heated or left for a certain time period, by which the liquid of the solution is evaporated and dried, so that the light emitting diodes 24-27 are arrayed and fixed at equal intervals along the lines of electric force between the metal electrodes 22 and 23.

As described above, according to the light emitting device manufacturing method of this embodiment, the light emitting diodes 24-27 can be arrayed between the protruding portions 22A-22D and the protruding portions 23A-23D of the metal electrodes 22, 23 at high precision with good controllability. Also in the method of this embodiment, it is difficult to determine orientation of the light emitting diodes 24-27 into one orientation (polarity), so that the orientation of the light emitting diodes 24-27 is not necessary in the state of FIG. 7. However, as described above, the array state is not limited to that of FIG. 7 for the light emitting device of this embodiment, and the light emitting diodes 24-27 may be randomly and mixedly oriented. Therefore, the manufacturing method of this embodiment is suitable for manufacture of such light emitting devices as in this embodiment of the invention in which mixed orientations (polarities) of the light emitting diodes are involved. Further, the manufacturing method of this embodiment has been described on a case where four light emitting diodes are arrayed as an example. However, the light emitting device manufacturing method of the invention makes it possible to array and connect a multiplicity of minute light emitting diodes at a time between electrodes, hence it is especially advantageous for cases with smaller sizes of the light emitting diodes (e.g., 100 μm or less), a large number (e.g., 100 or more) of light emitting diodes are connected between the first electrode 22 and the second electrode 23.

In addition, this embodiment has been described on a case where the first electrode 22 and the second electrode 23 have the protruding portions 22A-22D and the protruding portions 23A-23D. However, also when the first, second electrodes have no such protruding portions as described above, this embodiment is applicable. In this case, the distance between the first electrode and the second electrode is set slightly shorten than the length of the light emitting diodes to be set in place.

Also, the light emitting device manufacturing method of this embodiment is applicable also to cases in which the light emitting diode circuit 203 having a plurality of parallel structure units of the light emitting device of the foregoing second electrode is fabricated. In this case, the first, second electrodes 22, 23 are placed at both ends of the individual parallel structure units 401-404, and the solution containing the light emitting diodes 311-316, 321-326, 331-336, 341-346 is applied to the insulating substrate 21 as in the above-described case. Then, with the voltage applied to between the first, second electrodes 22, 23, the light emitting diodes are arrayed and fixed between the first, second electrodes. Thereafter, the parallel structure units 401-404 are connected in series by interconnecting lines other than the first, second electrodes 22, 23, e.g., upper-part wiring or the like.

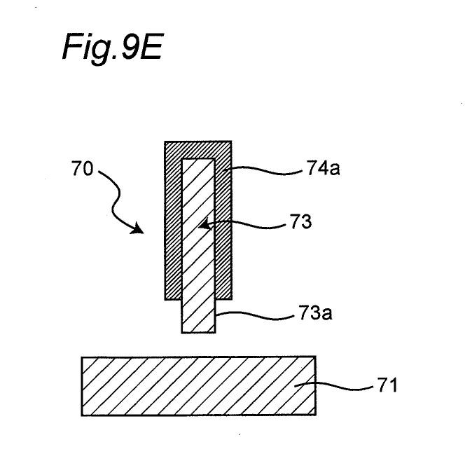

Next, an example of the manufacturing method for such rod-like structured light emitting diodes as described in the foregoing third embodiment will be explained with reference to FIGS. 9A-9E. First, as shown in FIG. 9A, a mask 72 having a growth hole 72a is formed on a substrate 71 formed of n-type GaN. Then, as shown in FIG. 9B, in a semiconductor core formation step, n-type GaN is crystal grown on the substrate 71 exposed by the growth hole 72a of the mask 72 by using MOCVD (Metal Organic Chemical Vapor Deposition) equipment to form a rod-like semiconductor core 73. In this case, the n-type GaN shows crystal growth of the hexagonal system, where making growth with a c-axis direction being a direction perpendicular to the surface of the substrate 71, by which a hexagonal cylinder-shaped semiconductor core can be obtained.

Next, as shown in FIG. 9C, in a semiconductor layer formation step, a semiconductor layer 74 of p-type GaN is formed all over the substrate 71 so as to cover the rod-like semiconductor core 73. Next, as shown in FIG. 9D, in an exposure step, regions except the semiconductor layer 74a part covering the semiconductor core 73 and the mask 72 are removed by lift-off, by which the substrate-side outer peripheral surface is exposed on the substrate 71 side of the rod-like semiconductor core 73, thus forming an exposure portion 73a. In this state, the end face of the semiconductor core 73 opposite to the substrate 71 is covered with the semiconductor layer 74a. Although lift-off is used in the exposure step of this embodiment, part of the semiconductor core may be exposed by etching.

Next, in a cut-off step, the substrate 71 is vibrated along the substrate plane by using ultrasonic waves (e.g., several tens kHz), by which stress acts on the semiconductor core 73 covered with the semiconductor layer 74a so that roots of the semiconductor core 73 erected on the substrate 71 close to the substrate 71 side are folded. As a result, the semiconductor core 73 covered with the semiconductor layer 74a is cut off from the substrate 71 as shown in FIG. 9E. In this way, a minute rod-like structured light emitting element 70 cut off from the substrate 71 can be manufactured. In this manufacturing method of rod-like structured light emitting diodes, the diameter of the rod-like structured light emitting element 70 is set to 1 μm and its length is set to 10 μm.

In the manufacturing method for light emitting diodes as described above, a semiconductor whose base material is GaN is used for the substrate 71, the semiconductor core 73 and the semiconductor layer 74a. However, semiconductors whose base material is GaAs, AlGaAs, GaAsP, InGaN, AlGaN, GaP, ZnSe, AlGaInP or the like may also be used. Although the substrate and the semiconductor core are set to the n type and the semiconductor layer is set to the p type, yet the rod-like structured light emitting diode may be reverse in conduction type. Further, the manufacturing method for rod-like structured light emitting diodes having a semiconductor core whose cross section is hexagonal cylinder-shaped has been described, but this is not limitative. The cross section may be circular or elliptical rod-like shape, and rod-like structured light emitting diodes having a rod-like semiconductor core whose cross section is triangular or other polygonal-shaped can also be fabricated by a manufacturing method similar to the above-described one. Further, in the light emitting diode manufacturing method, the diameter of the rod-like structured light emitting diode is set to 1 μm and its length is set to 10 μm, hence the micro-order size. However, the rod-like structured light emitting diode may be a nano-order sized element having a diameter and a length, at least a diameter, less than 1 μm. In the rod-like structured light emitting diode, the diameter of the semiconductor core is preferably not less than 500 nm and not more than 100 μm. As compared with rod-like structured light emitting diodes of several tens nm to several hundreds nm, variations in the diameter of the semiconductor core can be reduced, and variations in light emission area, i.e., emission characteristics can be reduced, so that the yield can be improved.

In the above light emitting diode manufacturing method, the semiconductor core 73 is crystal grown by using MOCVD equipment. However, the semiconductor core may also be formed by using other crystal growth equipment such as MBE (Molecular Beam Epitaxial) equipment. Also, although the semiconductor core is crystal grown on the substrate by using a mask having a growth hole, yet the semiconductor core may also be crystal grown from a metal seed with the metal seed placed on the substrate. Further, in the light emitting device manufacturing method, the semiconductor core 73 covered with the semiconductor layer 74a is cut off from the substrate 71 by using ultrasonic waves. However, without being limited to this, the semiconductor core may also be cut off from the substrate mechanically by using a cutting tool. In this case, a plurality of minute rod-like structured light emitting elements provided on the substrate can be cut off in short time by a simple means.

Furthermore, the rod-like structured light emitting diode manufactured by the light emitting diode manufacturing method may be not only the light emitting diode of the foregoing third embodiment but also the light emitting diodes of the foregoing first and second embodiments.

### Fifth Embodiment

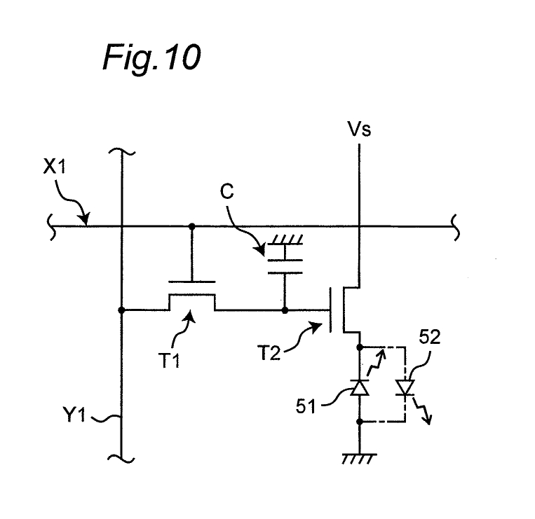

Next, FIG. 10 shows a circuit of one pixel of an LED (Light Emitting Diode) display which is a fifth embodiment of the invention. This fifth embodiment includes any one of the light emitting devices described in the foregoing first, second and third embodiments or the light emitting device manufactured by the manufacturing method of the foregoing fourth embodiment. As shown in FIG. 10, one of a plurality of light emitting diodes included in the light emitting device is included as a pixel LED 51 of one pixel. It is noted that the pixel LED 51 may be a pixel LED 52 of an opposite polarity to the pixel LED 51.

The LED display of this fifth embodiment is the active matrix address type one, in which a selective voltage pulse is fed to a row address line X1, and a data signal is fed to a column address line Y1. As the selective voltage pulse is inputted to a gate of a transistor T1 so that the transistor T1 is turned on, the data signal is transferred from source to drain of the transistor T1, thus the data signal being stored as a voltage in a capacitor C. A transistor T2 is for driving the pixel LED 51, and the pixel LED 51 is connected via the transistor T2 to AC power supply Vs. Therefore, as the transistor T2 is turned on by the data signal derived from the transistor T1, the pixel LED 51 is driven with the AC voltage by the AC power supply Vs.

In the LED display of this embodiment, the one pixel shown in FIG. 10 is arrayed in matrix. The pixel LEDs 51 or pixel LEDs 52 arrayed in matrix as well as the transistors T1, T2 are formed on a substrate. On the substrate, the pixel LEDs 51 or 52 of individual pixels can be arrayed between the first electrode and the second electrode by the manufacturing method described in the foregoing fourth embodiment, making it possible to manufacture a light emitting device in which the plurality of pixel LEDs 51, 52 are arrayed at random. Thus, the manufacture of the LED display in this embodiment becomes easy to accomplish, and the manufacturing cost can be cut down.

In addition, when a light emitting device to be used in display-use backlights or illuminating devices is given by any one of the light emitting devices as described in the above first, second and third embodiments or a light emitting device manufactured by the manufacturing method of the above fourth embodiment, the manufacture of the light emitting device becomes easier to accomplish and its manufacturing cost can be cut down. Further, usable as the semiconductor for fabricating the light emitting diodes described in the individual embodiments are, for example, GaN, GaAs, GaP, AlGaAs, GaAsP, InGaN, AlGaN, ZnSe, AlGaInP, and the like. Moreover, the light emitting diodes may be those having the quantum well structure for improvement in luminous efficacy.

### Sixth Embodiment

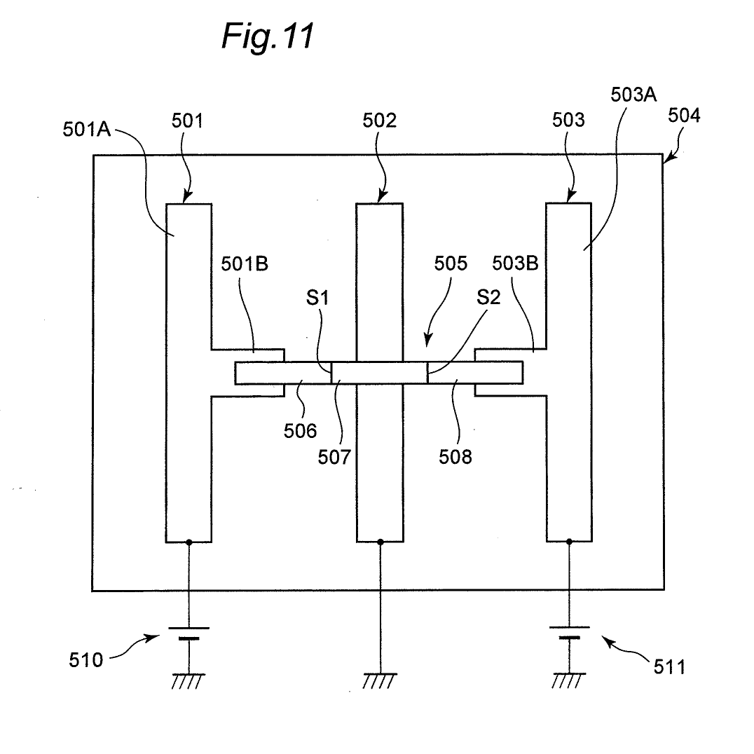

Next, a sixth embodiment of the light emitting device according to the invention will be described with reference to FIG. 11. FIG. 11 is a plan view schematically showing a sixth embodiment of the light emitting device according to the invention.

The light emitting device of this sixth embodiment includes a first electrode 501, a second electrode 502, a third electrode 503 and a rod-like light emitting element 505, where the first to third electrodes 501-503 are formed on a substrate 504. The first to third electrodes 501-503 are arrayed in order on the substrate 504, and the first electrode 501 has a base portion 501A extending in a direction perpendicular to the array direction, and a protruding portion 501B protruding from a generally center of the base portion 501A toward the second electrode 502. The third electrode 503 has a base portion 503A extending in a direction perpendicular to the array direction, and a protruding portion 503B protruding from a generally center of the base portion 503A toward the second electrode 502. Then, the second electrode 502 extends in a direction perpendicular to the array direction between the first electrode 501 and the third electrode 503.

The rod-like light emitting element 505 has a p-type first region 506 as a first-conductive-type first region, an n-type second region 507 as a second-conductive-type second region, and a p-type third region 508 as a first-conductive-type third region. The p-type first region 506, the n-type second region 507, and the p-type third region 508 are positioned side by side in order from the first electrode 501 toward the third electrode 503. The p-type first region 506 is connected to the protruding portion 501B of the first electrode 501, the n-type second region 507 is connected to the second electrode 502, and the p-type third region 508 is connected to the protruding portion 503B of the third electrode 503.

A DC (Direct Current) power supply 510 is connected between the first electrode 501 and the ground, and a DC power supply 511 is connected between the third electrode 503 and the ground. The second electrode 502 is connected to the ground. An anode of the DC power supply 510 is connected to the first electrode 501, and a cathode of the DC power supply 510 is connected to the ground. An anode of the DC power supply 511 is connected to the third electrode 503, and a cathode of the DC power supply 511 is connected to the ground.

Therefore, a current flows from the p-type first region 506 toward the n-type second region 507, so that light is emitted at a p-n junction surface S1 between the p-type first region 506 and the n-type second region 507. Also, a current flows from the p-type third region 508 toward the n-type second region 507, so that light is emitted at a junction surface S2 between the p-type third region 508 and the n-type second region 507.

According to the light emitting device of this embodiment, the p-type first region 506 and the p-type third region 508 are placed on both sides of the n-type second region 507 of the rod-like light emitting element 505. Therefore, the orientation of the rod-like light emitting element 505 is reverse to that of FIG. 1, i.e., connection of the first, third regions 506, 508 of the rod-like light emitting element 505 relative to the first, third electrodes 501, 503 is reversed, so that even if the p-type third region 508 is connected to the first electrode 501 and the p-type first region 506 is connected to the third electrode 503, the diode polarity is not changed, it is possible to fulfill normal light emission. Therefore, according to the light emitting device of this embodiment, the connection of the first, third regions 506, 508 relative to the first, third electrodes 501, 503 during the manufacturing process may be reversed, so that marks or shapes for discrimination of orientation of the rod-like light emitting element 505 are no longer necessary, allowing a simplification of the manufacturing process as well as a cutdown of the manufacturing cost to be achieved. In particular, for smaller sizes of the rod-like light emitting element 505 with their maximum size not more than 100 μm, the work for uniformizing the orientation of the rod-like light emitting element 505 beforehand becomes difficult to achieve because of the minute-sized component parts, in which case the manufacturing process can be simplified to a considerable extent by virtue of this embodiment that eliminates the need for uniformizing the orientation of the rod-like light emitting element 505. Further, because of the small size of the rod-like light emitting element 505, which is not more than 100 μm, there occurs no heat accumulation in the emission regions, so that power decrease or life decrease due to heat can be prevented.

In this embodiment, the first, third regions 506, 508 of the rod-like light emitting element 505 are set to the p type, while the second region 507 is set to the n type. However, it is also possible that the first, third regions 506, 508 are set to the n type while the second region 507 is set to the p type. In this case, the anode of the DC power supply 510 is connected to the ground and the cathode of the DC power supply 510 is connected to the first electrode 501, while the anode of the DC power supply 511 is connected to the ground and the cathode of the DC power supply 511 is connected to the third electrode 503.

Also, the DC power supplies 510, 511 do not need to be provided two in number, and either one of them will do, whichever it is. In this case, light is emitted by one junction surface out of the two junction surfaces S1, S2, where reversal of the orientation of the rod-like light emitting element 505 does not cause a change of the diode polarity, making it still possible to fulfill normal light emission. For example, with the DC power supply 510 alone provided, a current flows from the p-type first region 506 toward the n-type second region 507, so that light is emitted at the p-n junction surface S1 between the p-type first region 506 and the n-type second region 507.

### Seventh Embodiment

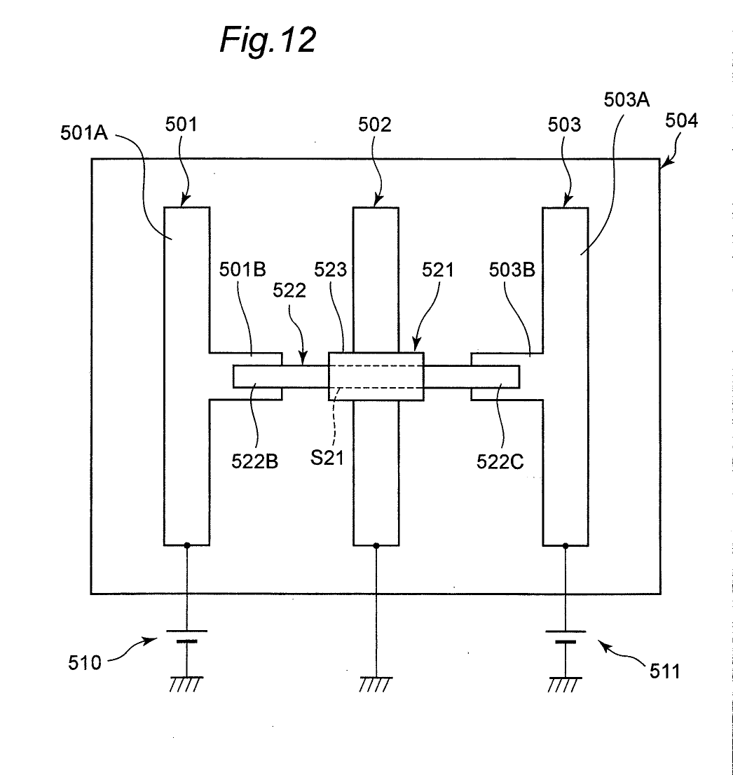

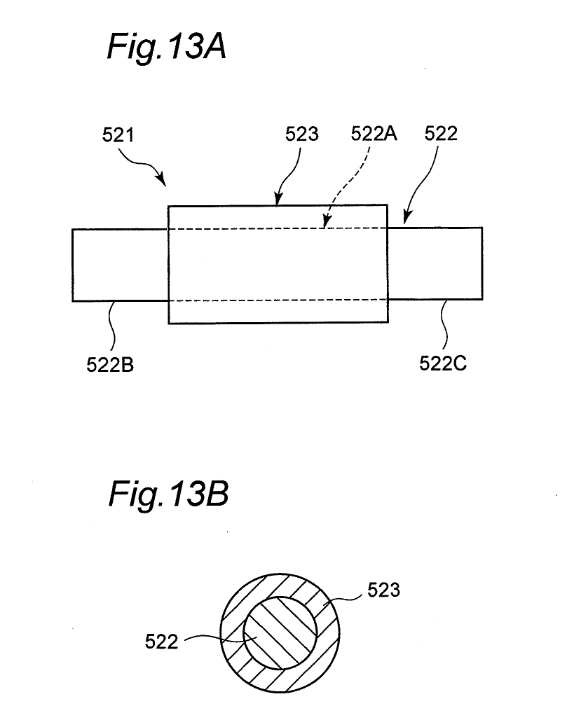

Next, a seventh embodiment of the light emitting device according to the invention will be described with reference to FIGS. 12, 13A and 13B. FIG. 12 is a schematic plan view showing the seventh embodiment, FIG. 13A is a side view of a rod-like light emitting element 521 included in the seventh embodiment, and FIG. 13B is a sectional view of the rod-like light emitting element 521. This seventh embodiment differs from the sixth embodiment only in that the rod-like light emitting element 505 of the foregoing sixth embodiment is replaced with the rod-like light emitting element 521 shown in FIGS. 13A and 13B. Therefore, in this seventh embodiment, like component members in conjunction with the above sixth embodiment are designated by like reference signs, and the description will be made mainly on the differences from the sixth embodiment.

The rod-like light emitting element 521 has a p-type columnar-shaped core portion 522 and an n-type cylindrical-shaped shell portion 523. The cylindrical-shaped shell portion 523 covers an outer peripheral surface 522A of the columnar-shaped core portion 522. Both end portions 522B, 522C of the columnar-shaped core portion 522 are protruded and exposed from both ends of the cylindrical-shaped shell portion 523. The n-type cylindrical-shaped shell portion 523 serves as a second region, and the p-type columnar-shaped core portion 522 serves as first and third regions. In this rod-like light emitting element 521, the end portion 522B of the p-type columnar-shaped core portion 522 is connected to the protruding portion 501B of the first electrode 501 on the substrate 504, and the end portion 522C of the core portion 522 is connected to the protruding portion 503B of the third electrode 503. Also, the cylindrical-shaped shell portion 523 is connected to the second electrode 502.

In the light emitting device of this seventh embodiment, with the DC power supply 510 connected between the first electrode 501 and the ground, a current flows from the end portion 522B of the p-type core portion 522 toward the n-type shell portion 523, so that light is emitted at a p-n junction surface S21 between the p-type core portion 522 and the n-type shell portion 523. Also, with the DC power supply 511 connected between the third electrode 503 and the ground, a current flows from the end portion 522C of the p-type core portion 522 toward the n-type shell portion 523, so that light is emitted at the p-n junction surface S21 between the p-type core portion 522 and the n-type shell portion 523. According to the rod-like light emitting element 521 of this seventh embodiment, as compared with the p-n junction surface S1 of the rod-like light emitting element 505 of the foregoing sixth embodiment, the p-n junction surface S21 between the columnar-shaped core portion 522 and the cylindrical-shaped shell portion 523 can be made larger, so that greater emission intensity can be obtained.

Also in this seventh embodiment, the end portion 522B and the end portion 522C of the p-type core portion 522 are placed on both sides of the n-type cylindrical-shaped shell portion 523. Therefore, the orientation of the rod-like light emitting element 521 is reverse to that of FIG. 12, and even if the connection of the end portions 522B, 522C of the core portion 522 of the rod-like light emitting element 521 relative to the first, third electrodes 501, 503 is reversed, the diode polarity is not changed, so that it is possible to fulfill normal light emission. Therefore, according to the light emitting device of this embodiment, the connection of the end portions 522B, 522C of the core portion relative to the first, third electrodes 501, 503 during the manufacturing process may be reversed, so that marks or shapes for discrimination of orientation of the rod-like light emitting element 521 are no longer necessary, allowing a simplification of the manufacturing process as well as a cutdown of the manufacturing cost to be achieved. In particular, for smaller sizes of the rod-like light emitting element 521 with their maximum size not more than 100 μm, the work for uniformizing the orientation of the rod-like light emitting element 521 beforehand becomes difficult to achieve because of the minute-sized component parts, in which case the manufacturing process can be simplified to a considerable extent by this embodiment. Further, because of the small size of the rod-like light emitting element 521, which is not more than 100 μm, there occurs no heat accumulation in the emission regions, so that power decrease or life decrease due to heat can be prevented.

In this embodiment, the columnar-shaped core portion 522 of the rod-like light emitting element 521 is set to the p type, while the cylindrical-shaped shell portion 523 is set to the n type. However, it is also possible that the core portion 522 is set to the n type while the shell portion 523 is set to the p type. In this case, the anode of the DC power supply 510 is connected to the ground and the cathode of the DC power supply 510 is connected to the first electrode 501, while the anode of the DC power supply 511 is connected to the ground and the cathode of the DC power supply 511 is connected to the third electrode 503. Also, in this embodiment, the core portion 522 is set columnar-shaped and the shell portion 523 is set cylindrical-shaped. However, it is also possible that the core portion 522 is set polygonal prism-shaped and the shell portion 523 is set polygonal cylinder-shaped. For example, it is allowable that the core portion 522 is set triangular prism-shaped, quadrangular prism-shaped, pentagonal prism-shaped or hexagonal prism-shaped while the shell portion 523 is triangular cylinder-shaped, quadrangular cylinder-shaped, pentagonal cylinder-shaped or hexagonal cylinder-shaped. It is further allowable that the core portion 522 is elliptic column-shaped and the shell portion 523 is elliptic cylinder-shaped.

Also, the DC power supplies 510, 511 do not need to be provided two in number, and either one of them will do, whichever it is. Even in this case, reversal of the orientation of the rod-like light emitting element 521 does not cause a change of the diode polarity, making it still possible to fulfill normal light emission. For example, with the DC power supply 510 alone provided, a current flows from the end portion 522B of the p-type core portion 522 toward the n-type shell portion 523, so that light is emitted at the p-n junction surface S21 between the p-type core portion 522 and the n-type shell portion 523.

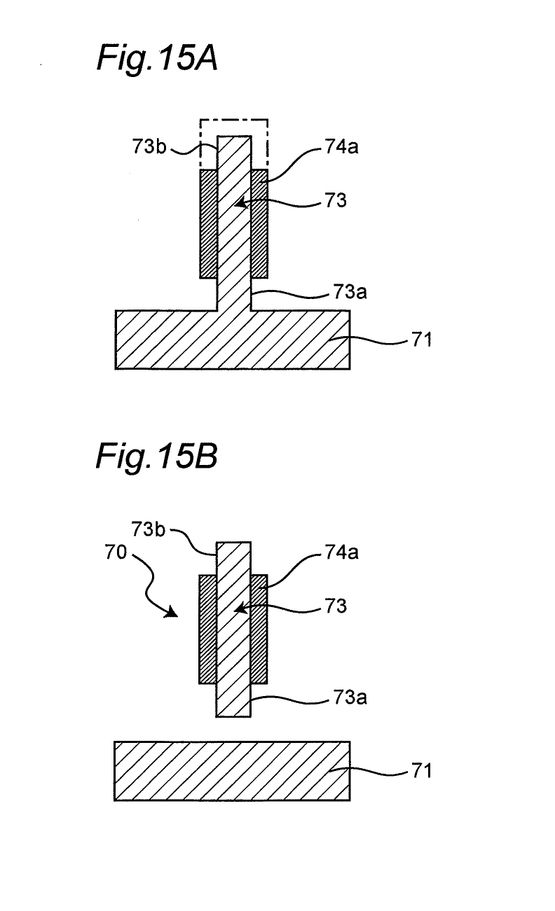

Next, an example of the manufacturing method for such rod-like structured light emitting elements as described in the foregoing seventh embodiment will be explained with reference to FIGS. 9A-9C, 15A, and 15B. First, as shown in FIG. 9A, a mask 72 having a growth hole 72a is formed on a substrate 71 formed of n-type GaN. Then, as shown in FIG. 9B, in a semiconductor core formation step, n-type GaN is crystal grown on the substrate 71 exposed by the growth hole 72a of the mask 72 by using MOCVD (Metal Organic Chemical Vapor Deposition) equipment to form a rod-like semiconductor core 73. In this case, the n-type GaN shows crystal growth of the hexagonal system, where making growth with a c-axis direction being a direction perpendicular to the surface of the substrate 71, by which a hexagonal cylinder-shaped semiconductor core can be obtained.

Next, as shown in FIG. 9C, in a semiconductor layer formation step, a semiconductor layer 74 of p-type GaN is formed all over the substrate 71 so as to cover the rod-like semiconductor core 73. Next, as shown in FIG. 15A, in an exposure step, regions except the semiconductor layer 74a part covering the semiconductor core 73 and the mask 72 are removed by lift-off, by which the substrate-side outer peripheral surface is exposed on the substrate 71 side of the rod-like semiconductor core 73, thus forming an exposure portion 73a. In this state, the end face of the semiconductor core 73 opposite to the substrate 71 is covered with the semiconductor layer 74a. Although lift-off is used in the exposure step of this embodiment, part of the semiconductor core may be exposed by etching. Next, the semiconductor core 73 covered with the semiconductor layer 74, except its upper end portion, is buried by the mask, and the outer peripheral surface of the semiconductor core 73 opposite to the substrate 71 is exposed by isotropic dry etching to form another exposure portion 73b, after which the mask is removed.

Next, in a cut-off step, the substrate 71 is vibrated along the substrate plane by using ultrasonic waves (e.g., several tens kHz), by which stress acts on the semiconductor core 73 covered with the semiconductor layer 74a so that roots of the semiconductor core 73 erected on the substrate 71 close to the substrate 71 side are folded. As a result, the semiconductor core 73 covered with the semiconductor layer 74a is cut off from the substrate 71 as shown in FIG. 15B. In this way, a minute rod-like structured light emitting element 70 cut off from the substrate 71 can be manufactured. In this manufacturing method of rod-like structured light emitting elements, the diameter of the rod-like structured light emitting element 70 is set to 1 μm and its length is set to 10 μm.

In the manufacturing method for light emitting elements as described above, a semiconductor whose base material is GaN is used for the substrate 71, the semiconductor core 73 and the semiconductor layer 74a. However, semiconductors whose base material is GaAs, AlGaAs, GaAsP, InGaN, AlGaN, GaP, ZnSe, AlGaInP or the like may also be used. Although the substrate and the semiconductor core are set to the n type and the semiconductor layer is set to the p type, yet the rod-like structured light emitting diode may be reverse in conduction type. Further, the manufacturing method for rod-like structured light emitting diodes having a semiconductor core whose cross section is hexagonal cylinder-shaped has been described, but this is not limitative. The cross section may be circular or elliptical rod-like shape, and rod-like structured light emitting diodes having a rod-like semiconductor core whose cross section is triangular or other polygonal-shaped can also be fabricated by the manufacturing method similar to the above-described one. Further, in the light emitting element manufacturing method, the diameter of the rod-like structured light emitting element is set to 1 μm and its length is set to 10 μm, hence the micro-order size. However, the rod-like structured light emitting element may be a nano-order sized elements having a diameter and a length, at least a diameter less than 1 μm. In the rod-like structured light emitting element, the diameter of the semiconductor core is preferably not less than 500 nm and not more than 100 μm. As compared with rod-like structured light emitting elements of several tens nm to several hundreds nm, variations in the diameter of the semiconductor core can be reduced, variations in light emission area, i.e., emission characteristics can be reduced, so that the yield can be improved.

In the above light emitting element manufacturing method, the semiconductor core 73 is crystal grown by using MOCVD equipment. However, the semiconductor core may also be formed by using other crystal growth equipment such as MBE (Molecular Beam Epitaxial) equipment. Also, although the semiconductor core is crystal grown on the substrate by using a mask having a growth hole, yet the semiconductor core may also be crystal grown from a metal seed with the metal seed placed on the substrate. Further, in the light emitting element manufacturing method, the semiconductor core 73 covered with the semiconductor layer 74a is cut off from the substrate 71 by using ultrasonic waves. However, without being limited to this, the semiconductor core may also be cut off from the substrate mechanically by using a cutting tool. In this case, a plurality of minute rod-like structured light emitting elements provided on the substrate can be cut off in short time by a simple means.

### Eighth Embodiment

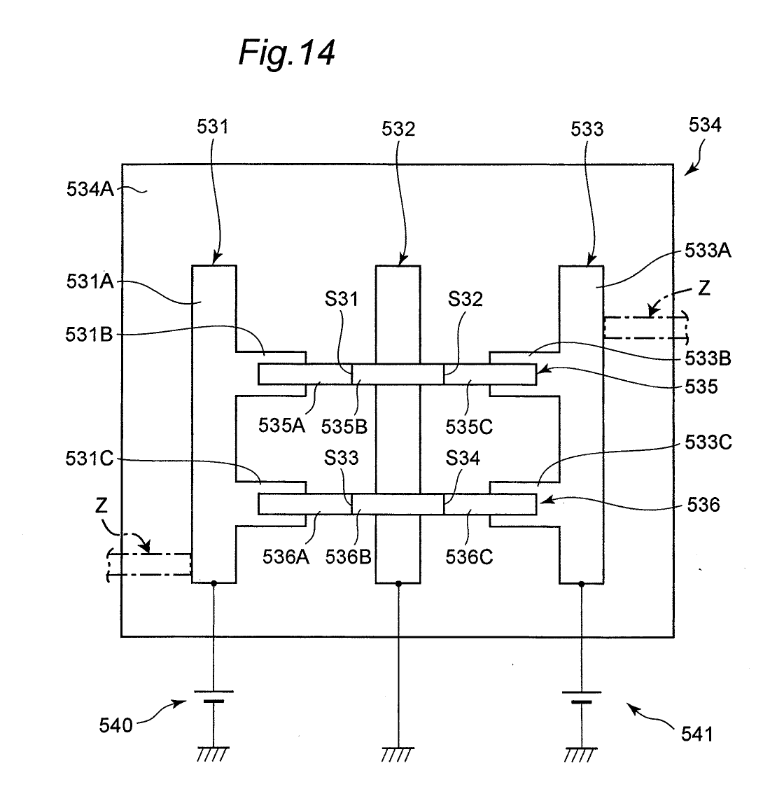

Next, an eighth embodiment of the light emitting device according to the invention will be described with reference to FIG. 14. FIG. 14 is a schematic plan view showing the eighth embodiment.

This eighth embodiment includes a first electrode 531, a second electrode 532, a third electrode 533 and two rod-like light emitting elements 535, 536 similar in structure to the rod-like light emitting element 505 of the foregoing sixth embodiment, where the first to third electrodes 531-533 are formed on a substrate 534 similar to the substrate 504. The first to third electrodes 531-533 are arrayed in order on the substrate 534, and the first electrode 531 has a base portion 531A extending in a direction perpendicular to the array direction, and two protruding portions 531B, 531C protruding from the base portion 531A toward the second electrode 532. The third electrode 533 has a base portion 533A extending in a direction perpendicular to the array direction, and two protruding portions 533B, 533C protruding from the base portion 533A toward the second electrode 532. Then, the second electrode 532 extends in a direction perpendicular to the array direction between the first electrode 531 and the third electrode 533.

The rod-like light emitting element 535 has a p-type first region 535A, an n-type second region 535B, and a p-type third region 535C. The p-type first region 535A is connected to the protruding portion 531B of the first electrode 531, the n-type second region 535B is connected to the second electrode 532, and the p-type third region 535C is connected to the protruding portion 533B of the third electrode 533. Also, the rod-like light emitting element 536 has a p-type first region 536A, an n-type second region 536B, and a p-type third region 536C. The p-type first region 536A is connected to the protruding portion 531C of the first electrode 531, the n-type second region 536B is connected to the second electrode 532, and the p-type third region 536C is connected to the protruding portion 533C of the third electrode 533.

A DC power supply 540 is connected between the first electrode 531 and the ground, and a DC power supply 541 is connected between the third electrode 533 and the ground. The second electrode 532 is connected to the ground. An anode of the DC power supply 540 is connected to the first electrode 531, and a cathode of the DC power supply 540 is connected to the ground. An anode of the DC power supply 541 is connected to the third electrode 533, and a cathode of the DC power supply 541 is connected to the ground.

Therefore, a current flows from the p-type first region 535A toward the n-type second region 535B in the rod-like light emitting element 535, so that light is emitted at a p-n junction surface S31 between the p-type first region 535A and the n-type second region 535B. Also, a current flows from the p-type third region 535C toward the n-type second region 535B, so that light is emitted at a junction surface S32 between the p-type third region 535C and the n-type second region 535B. Also, a current flows from the p-type first region 536A toward the n-type second region 536B in the rod-like light emitting element 536, so that light is emitted at a junction surface S33 between the p-type first region 536A and the n-type second region 536B. Further, a current flows from the p-type third region 536C toward the n-type second region 536B, so that light is emitted at a junction surface S34 between the p-type third region 536C and the n-type second region 536B.

According to the light emitting device of this eighth embodiment, the p-type first region 535A and the p-type third region 535C are placed on both sides of the n-type second region 535B of the rod-like light emitting element 535, and the p-type first region 536A and the p-type third region 536C are placed on both sides of the n-type second region 536B of the rod-like light emitting element 536. Therefore, the orientation of the rod-like light emitting element 535 is reverse to that of FIG. 14, i.e., connection of the first, third regions 535A, 535C of the rod-like light emitting element 535 relative to the first, third electrodes 531, 533 is reversed, the diode polarity is not changed, so that it is possible to fulfill normal light emission. This is the case also with another rod-like light emitting element 536.

Therefore, according to the light emitting device of this embodiment, the connection of the first, third regions 535A, 535C relative to the first, third electrodes 531, 533 during the manufacturing process may be reversed, and the connection of the first, third regions 536A, 536C relative to the first, third electrodes 531, 533 may be reversed. Thus, the rod-like light emitting elements 535, 536 do not need to be uniformized in orientation, the manufacturing process can be simplified, and marks or shapes for discrimination of orientation of the rod-like light emitting elements 535, 536 are no longer necessary, so that the manufacturing cost can be cut down. In particular, for smaller sizes of the rod-like light emitting elements 535, 536 with their maximum size not more than 100 μm, the work for uniformizing the orientation of the rod-like light emitting elements 535, 536 beforehand becomes difficult to achieve because of the minute-sized component parts, in which case the manufacturing process can be simplified to a considerable extent by virtue of this embodiment that eliminates the need for uniformizing the orientation of the rod-like light emitting elements 535, 536. Further, because of the small size of the rod-like light emitting elements 535, 536, which are not more than 100 μm, there occurs no heat accumulation in the emission regions, so that power decrease or life decrease due to heat can be prevented.

In this embodiment, the first, third regions 535A, 535C, 536A, 536C of the rod-like light emitting elements 535, 536 are set to the p type, while the second regions 535B, 536B are set to the n type. However, it is also possible that the first, third regions 535A, 535C, 536A, 536C are set to the n type while the second regions 535B, 536B are set to the p type. In this case, the anode of the DC power supply 540 is connected to the ground and the cathode of the DC power supply 540 is connected to the first electrode 531, while the anode of the DC power supply 541 is connected to the ground and the cathode of the DC power supply 541 is connected to the third electrode 533.

Also, the DC power supplies 540, 541 do not necessarily need to be provided two in number, and either one of them will do, whichever it is. In this case, light is emitted by only two junction surfaces out of the four junction surfaces S31-S34, where reversal of the orientation of one or both of the rod-like light emitting elements 535, 536 does not cause a change of the diode polarity, making it still possible to fulfill normal light emission. For example, with the DC power supply 540 alone provided, currents flow from the p-type first region 535A toward the n-type second region 535B, and from the p-type first region 536A toward the n-type second region 536B, respectively, so that light is emitted at the p-n junction surfaces S31, S33.

Also in this embodiment, the first, third electrodes 531, 533 each have two protruding portions 531B, 531C, 533B, 533C. However, it is also possible that the first, third electrodes 531, 533 each have three or more protruding portions, while three or more rod-like light emitting elements similar in construction to the rod-like light emitting elements 535, 536 are connected between the three or more protruding portions of the first electrode and three or more protruding portions of the third electrode. For example, 100 or more rod-like light emitting elements similar in construction to the rod-like light emitting elements 535, 536 may be connected between 100 or more protruding portions of the first electrode and 100 or more protruding portions of the third electrode.

### Ninth Embodiment

Next, a manufacturing method for light emitting elements as a ninth embodiment of the invention will be described. In this ninth embodiment, a method for manufacturing such a light emitting device as described in the foregoing eighth embodiment will be explained with reference to FIG. 14.

In this ninth embodiment, first, a substrate 534 having a first electrode 531, a second electrode 532 and a third electrode 533 formed on its surface 534A is prepared. This substrate 534 is an insulating substrate, and the first, second, third electrodes 531, 532, 533 are metal electrodes. As an example, metal electrodes 531, 532, 533 of desired electrode shape may be formed on the surface 534A of the insulating substrate 534 by utilizing printing techniques. It is also possible that with a metal film and a photoreceptor film stacked uniformly on the surface 534A of the insulating substrate 534, the photoreceptor film is subjected to exposure and development of a desired electrode pattern, and then with the patterned photoreceptor film used as a mask, the metal film is etched, by which the first to third electrodes 531-533 can be formed. Usable as the metal material for forming the metal electrodes 531-533 are gold, silver, copper, iron, tungsten, tungsten nitride, aluminum, tantalum, alloys of these metals, and the like. Also, the insulating substrate 534 is made of such an insulator as glass, ceramic, alumina or resin, or such a semiconductor as silicon on a surface of which silicon oxide is formed so that the surface has insulative property. When a glass substrate is used, a ground insulative film such as silicon oxide or silicon nitride is formed on the surface, desirably.

The distance between the protruding portions 531B, 531C of the first electrode 531 and the protruding portions 533B, 533C of the third electrode 533 is, preferably, slightly shorten than the length of the rod-like light emitting elements 535, 536. As an example, the distance is desirably 6 to 9 μm when the length of the rod-like light emitting elements 535, 536 is 10 μm. That is, the distance is desirably about 60 to 90% of the length of the rod-like light emitting elements 535, 536, more preferably, 80 to 90% of the length.

Next, the procedure for arraying the rod-like light emitting elements 535, 536 on the insulating substrate 534 will be explained. First, isopropyl alcohol (IPA) as a solution containing the light emitting diodes 535, 536 is thinly applied on the insulating substrate 534. Other than IPA, usable as the solution are ethylene glycol, propylene glycol, methanol, ethanol, acetone, or mixtures of those materials, as well as liquids formed from other organic matters, water or the like. However, when a large current flows through the liquid between the metal electrodes 531, 532, 533, a desired potential difference can no longer be applied to between the metal electrodes 531, 532, 533. In such a case, the overall surface of the insulating substrate 534 may properly be coated with an insulative film of about 10 nm to 30 nm so as to make the metal electrodes 531, 532, 533 covered therewith.

A thickness to which the IPA containing the rod-like light emitting elements 535, 536 is applied is such that the rod-like light emitting elements 535, 536 are movable in the liquid so that the rod-like light emitting elements 535, 536 can be arrayed in the step of subsequently arraying the rod-like light emitting elements 535, 536. Accordingly, the thickness is equal to or more than the thickness of the rod-like light emitting elements 535, 536, e.g., several μm to several mm. Too small thicknesses of application would cause difficulty for the rod-like light emitting elements 535, 536 to move, while too large thicknesses would cause the time of drying the liquid to be elongated. Preferably, the thickness is 100 to 500 μm. Also, the number of rod-like light emitting elements relative to the quantity of IPA is preferably 1×10⁴/cm³ to 1×10⁷/cm³.

For application of IPA containing the rod-like light emitting elements 535, 536 onto the insulating substrate 534, it is appropriate that a frame (not shown) is formed on outer peripheries of the metal electrodes 531-533 for array of the rod-like light emitting elements 535, 536, and IPA containing the rod-like light emitting elements 535, 536 is filled inside the frame to a desired thickness. However, when the IPA containing the rod-like light emitting elements 535, 536 has viscosity, it is implementable to achieve application of a desired thickness without the need for the frame. Liquids such as the IPA or ethylene glycol, propylene glycol, methanol, ethanol, acetone or mixtures of those, or liquids formed from other organic matters, or water or other liquid are desirably as low in viscosity as possible in terms of the step of arraying the rod-like light emitting elements 535, 536, and also desirably easy to evaporate by heating.

Next, a potential difference is given to between the metal electrodes 531, 533. Given to the metal electrode 532 is a potential of an intermediate level between a potential of the metal electrode 531 and another potential of the metal electrode 533 as an example. The potential difference between the metal electrodes 531 and 533 is set to 0.5 V or 1 V, as an example. As this potential difference between the metal electrodes 531 and 533, a potential difference of 0.1-10 V may be applied, where potential differences of 0.1 V or less would cause the rod-like light emitting elements 535, 536 to come to be disarrayed in posture, while potential differences of 10 V or more gives rise to a problem of insulation between the metal electrodes. Accordingly, the potential difference is preferably set to 0.5 V-5 V, more preferably to about 0.5 V. When a potential VL is given to the metal electrode 531 while a potential VH (VL<VH) higher than the potential VL is given to the metal electrode 533, negative charge is induced to the metal electrode 531 while positive charge is induced to the metal electrode 533. With the rod-like light emitting elements 535, 536 approaching the metal electrodes 531, 533, positive charge is induced to one side of the rod-like light emitting elements 535, 536 closer to the metal electrode 531, while negative charge is induced to the other side closer to the metal electrode 533. The induction of electric charge to the rod-like light emitting elements 535, 536 is due to electrostatic induction. Therefore, the rod-like light emitting elements 535, 536 are postured along lines of electric force occurring between the metal electrodes 531, 532, 533, and moreover because of nearly equal charge being induced to the rod-like light emitting elements 535, 536, the rod-like light emitting elements 535, 536 are arrayed regularly with nearly equal intervals in a certain direction by the repulsive force due to the electric charge. In this case, assuming that the surfaces of the metal electrodes 531, 532, 533 are coated with insulative film and moreover that the potential difference given to between the metal electrodes 531, 533 is constant (DC), ions of an opposite polarity to the potential of the metal electrodes 531, 533 are induced to the surfaces of the coated insulative film on the metal electrodes 531, 533, so that the electric field in the solution becomes considerably weakened. In such a case, it is preferable that AC voltage is applied to between the metal electrodes 531, 533. As an example, a reference potential (ground potential) is given to the electrode 532, while AC voltages different in phase by 180° to each other are applied to the electrodes 531, 533. As a result of this, the induction of ions of an opposite polarity to the potential of the metal electrodes 531, 533 can be prevented, so that the rod-like light emitting elements 535, 536 can be arrayed normally. In addition, frequency of the AC voltage applied to between the metal electrodes 531, 533 is preferably 10 Hz to 1 MHz. However, when the frequency of the AC voltage is less than 10 Hz, there is a possibility that the rod-like light emitting elements 535, 536 vibrate heavily so as to be disarrayed. On the other hand, when the frequency of the AC voltage applied to between the metal electrodes 531, 533 is beyond 1 MHz, the force with which the rod-like light emitting elements 535, 536 are sucked up to the metal electrodes 531, 533 is weakened, so that the rod-like light emitting elements 535, 536 are disarrayed by external disturbance. Therefore, for stabilized array of the rod-like light emitting elements 535, 536, it is more preferable that the frequency of the AC voltage is set to 50 Hz-1 kHz. Moreover, the waveform of the AC voltage, without being limited to sinusoidal wave, may be any one of rectangular wave, chopping wave, sawtooth wave or the like, whichever it varies periodically. In addition, the amplitude of the AC voltage is preferably set to about 0.5 V as an example.

As shown above, in this embodiment, since electric charge is generated to the rod-like light emitting elements 535, 536 by external electric field generated between the metal electrodes 531, 532, 533, so that the rod-like light emitting elements 535, 536 are sucked up to the metal electrodes 531, 532, 533 by attractive force of the electric charge. Therefore, it is necessary that the rod-like light emitting elements 535, 536 be sized movable in liquid. Accordingly, the permissible value of the size (maximum size) of the rod-like light emitting elements 535, 536 varies depending on the amount of liquid application (application thickness). The size (maximum size) of the rod-like light emitting elements 535, 536 has to be on the nano-scale for smaller amounts of liquid application, but the size of each rod-like light emitting element 535, 536 may be on the micron order for larger amounts of liquid application.

When the rod-like light emitting elements 535, 536 are not electrically neutral but positively or negatively charged as net, the rod-like light emitting elements 535, 536 cannot be stably arrayed only by giving a static potential difference (DC) to between the metal electrodes 531, 533. For example, when the rod-like light emitting element 535 is positively charged as net, the attractive force with the electrode 533, to which positive charge has been induced, is relatively weakened, so that the array of the rod-like light emitting element 535 to the metal electrodes 531, 533 becomes asymmetrical. In such a case, an AC voltage is preferably applied to the metal electrodes 531, 533. As an example, a reference potential (ground potential) is given to the electrode 532, while AC voltages different in phase by 180° to each other are applied to the electrodes 531, 533. As a result of this, the rod-like light emitting element 535, when electrically charged as net, can be held symmetrical in array. In addition, frequency of the AC voltage applied to between the metal electrodes 531, 533 is preferably 10 Hz to 1 MHz. However, when the frequency of the AC voltage is less than 10 Hz, there is a possibility that the rod-like light emitting elements vibrate heavily so as to be disarrayed. On the other hand, when the frequency of the AC voltage applied to between the metal electrodes 531, 533 is beyond 1 MHz, the force with which the rod-like light emitting elements 535, 536 are sucked up to the metal electrodes 531, 533 is weakened, so that the rod-like light emitting elements 535, 536 are disarrayed by external disturbance. Therefore, for stabilized array of the rod-like light emitting elements 535, 536, it is more preferable that the frequency of the AC voltage is set to 50 Hz-1 kHz. Moreover, the waveform of the AC voltage, without being limited to sinusoidal wave, may be any one of rectangular wave, chopping wave, sawtooth wave or the like, whichever it varies periodically. In addition, the amplitude of the AC voltage is preferably set to about 0.5 V as an example.

Soon after the beginning of the array of the rod-like light emitting elements 535, 536, the rod-like light emitting elements 535, 536 are arrayed between the protruding portions 531B, 531C of the first electrode 531 and the protruding portions 533B, 533C of the third electrode 533 as schematically shown in FIG. 14. The rod-like light emitting elements 535, 536 are arrayed in a posture perpendicular to the direction in which the first, second and third electrodes 531, 532, 533 extend so as to be arrayed at generally equal intervals in the extending direction. Electric fields are concentrated between the protruding portions 531B, 531C and the protruding portions 533B, 533C, and moreover repulsive force acts between the rod-like light emitting elements 535, 536 by the charge induced to the rod-like light emitting elements 535, 536, so that the rod-like light emitting elements 535, 536 are arrayed at generally equal intervals.

In addition, as shown by imaginary line in FIG. 14, rod-like light emitting elements Z which are contained in the solution but not included in the rod-like light emitting elements 535, 536 may be sucked to the base portion 531A of the first electrode 531 or the base portion 533A of the third electrode 533. In this case, the solution of IPA or the like is passed to around the base portions 531A, 533A of the first, third electrodes 531, 533 with the AC voltage kept applied to between the first, third electrodes 531, 533, by which the rod-like light emitting elements Z sucked to the first electrode 531 or the third electrode 533 can be removed. Thus, improvement of the yield can be achieved.

After the rod-like light emitting elements 535, 536 are arrayed between the protruding portions 531B, 531C of the first electrode 531 and the protruding portions 533B, 533C of the third electrode 533 in the way shown above, the substrate 534 is heated or left for a certain time period, by which the liquid of the solution is evaporated and dried, so that the rod-like light emitting elements 535, 536 are arrayed and fixed at equal intervals along the lines of electric force between the metal electrodes 522 and 523.

As described above, according to the light emitting device manufacturing method of this embodiment, the rod-like light emitting elements 535, 536 as minute as 100 μm for their maximum size can be placed at positions defined by the first, second, third electrodes 531, 532, 533 by using the so-called dielectrophoresis. In this manufacturing method, it is difficult to determine orientation of the rod-like light emitting elements 535, 536 into one orientation. Although connection of the first, third regions 535A, 535C of the rod-like light emitting elements 535, 536 relative to the first, third electrodes 531, 533 may be changed over, yet the above-described eighth embodiment keeps normal light emission even in this case, hence suitable as a manufacturing method for the light emitting device of the eighth embodiment.

Further, the manufacturing method of this embodiment has been described on a case where two rod-like light emitting elements are arrayed as an example. However, the light emitting element manufacturing method of the invention makes it possible to array and connect a multiplicity of minute light emitting elements at one time between the first, second, third electrodes, hence especially advantageous for cases with smaller sizes of the rod-like light emitting elements (e.g., 100 μm or less), large numbers (e.g., 100 or more) of rod-like light emitting elements are connected between the first electrode 531 and the third electrode 533.

### Tenth Embodiment

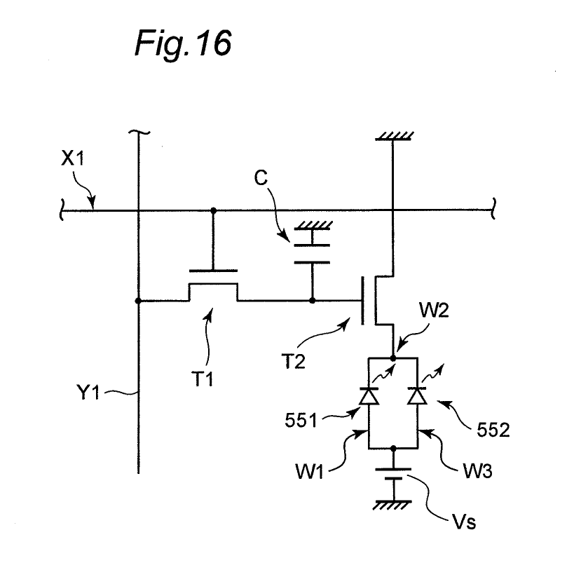

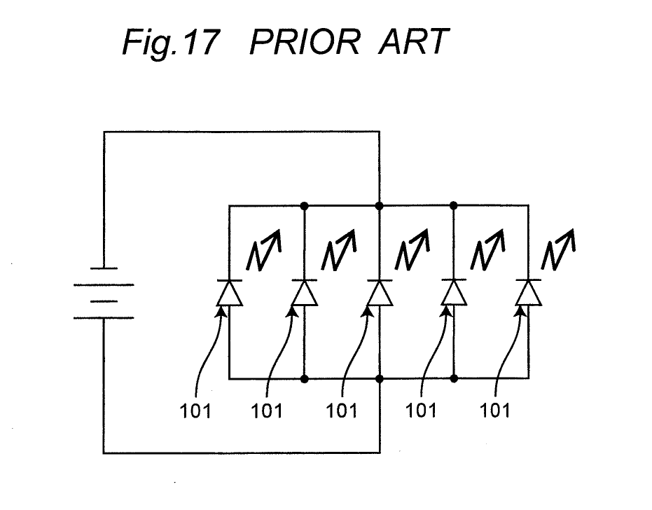

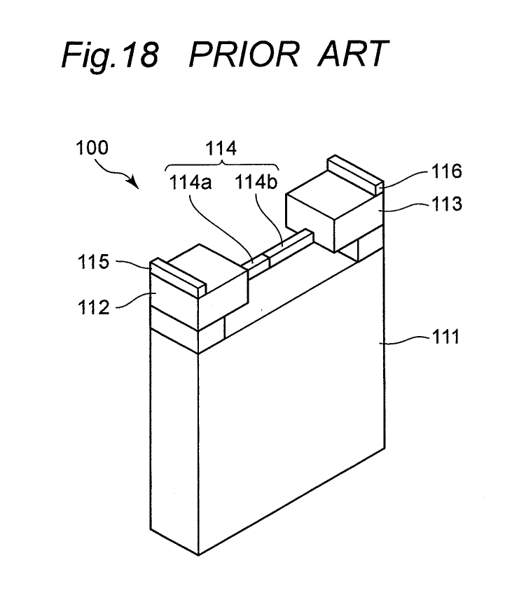

Next, FIG. 16 shows a circuit of one pixel of an LED (Light Emitting Diode) display as a tenth embodiment according to the invention. This tenth embodiment includes one of the light emitting devices described in the foregoing first to eighth embodiments, and has, as pixel LEDs 551, 552 for one pixel, one of the rod-like light emitting elements included in the light emitting device as shown in FIG. 16. In FIG. 16, places shown by reference signs W1, W3 correspond to the first, third electrodes, and a place shown by reference sign W2 corresponds to the second electrode.

The LED display of this tenth embodiment is the active matrix address type one, in which a selective voltage pulse is fed to a row address line X1, and a data signal is fed to a column address line Y1. As the selective voltage pulse is inputted to the gate of a transistor T1 so that the transistor T1 is turned on, the data signal is transferred from source to drain of the transistor T1, thus the data signal being stored as a voltage in a capacitor C. A transistor T2 is for driving the pixel LEDs 551, 552. Therefore, as the transistor T2 is turned on by the data signal derived from the transistor T1, the pixel LEDs 551, 552 are driven with the AC power supply Vs.

In the LED display of this embodiment, the one pixel shown in FIG. 16 is arrayed in matrix. The pixel LEDs 551, 552 arrayed in matrix as well as the transistors T1, T2 are formed on the substrate. On the substrate, the pixel LEDs 551, 552 of individual pixels can be arrayed relative to the first to third electrodes by the manufacturing method described in the foregoing ninth embodiment, making it possible to manufacture a light emitting device in which the plurality of rod-like light emitting elements serving as the pixel LEDs 551, 552 are arrayed in each pixel. Thus, the manufacture of the LED display in this embodiment becomes easy to accomplish, and the manufacturing cost can be cut down.

In addition, when a light emitting device to be used in display-use backlights or illuminating devices is given by any one of the light emitting devices as described in the above sixth, seventh and eighth embodiments, the manufacture of the light emitting device becomes easier to accomplish and its manufacturing cost can be cut down. Further, usable as the semiconductor for fabricating the rod-like light emitting elements described in the individual embodiments are, for example, GaN, GaAs, GaP, AlGaAs, GaAsP, InGaN, AlGaN, ZnSe, AlGaInP, and the like. Moreover, the rod-like light emitting elements may be those having the quantum well structure for improvement in luminous efficacy.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A light emitting device comprising:
a first electrode;
a second electrode; and
a light emitting diode circuit which has at least one parallel structure unit composed of a plurality of light emitting diodes connected in parallel between the first electrode and the second electrode, and which is connected between the first electrode and the second electrode, wherein
the plurality of light emitting diodes making up the parallel structure unit comprise:
first light emitting diodes which are placed so as to be forward oriented when the first electrode is set higher in potential than the second electrode, and
second light emitting diodes which are placed so as to be forward oriented when the second electrode is set higher in potential than the first electrode, and wherein
in the parallel structure unit,
the first light emitting diodes and the second light emitting diodes are mixedly placed, and
the plurality of light emitting diodes are driven with an AC voltage applied to between the first electrode and the second electrode by AC power supply.

2. The light emitting device as claimed in claim 1, wherein
the light emitting diode circuit is made up by series connection of a plurality of the parallel structure units.

3. The light emitting device as claimed in claim 1, wherein
the light emitting diode circuit has a singularity of the parallel structure unit,
the first light emitting diode has
an anode connected to the first electrode and a cathode connected to the second electrode, and
the second light emitting diode has
a cathode connected to the first electrode and an anode connected to the second electrode.

4. The light emitting device as claimed in claim 2, wherein
the plurality of parallel structure units are composed of a mutually equal number of light emitting diodes.

5. The light emitting device as claimed in claim 2, wherein
the parallel structure unit is composed of m (m is a natural number of 2 or more) light emitting diodes,
a plurality n (n is a natural number of 2 or more) of the parallel structure units are connected in series to build the light emitting diode circuit, and
the number m and the number n satisfy a relationship that 1−(1−(½)^{m-1})ⁿ≦0.05.

6. The light emitting device as claimed in claim 1, wherein
the number of the plural light emitting diodes is not less than 100 and not more than 100000000.

7. The light emitting device as claimed in claim 1, wherein
AC frequency of the AC power supply is not less than 60 Hz and not more than 1 MHz.

8. The light emitting device as claimed in claim 1, wherein
alternating current derived from the AC power supply is a rectangular wave.

9. The light emitting device as claimed in claim 1, wherein
the first electrode and the second electrode are formed on one substrate.

10. The light emitting device as claimed in claim 9, wherein
the first electrode and the second electrode extend along a surface of the substrate and are opposed to each other,
the first electrode has a plurality of protruding portions which are formed so as to protrude toward the second electrode and be arrayed side by side along an extending direction of the first and second electrodes,
the second electrode has a plurality of protruding portions which are formed so as to protrude toward the first electrode and be arrayed side by side along the extending direction,
the protruding portions of the first electrode and the protruding portions of the second electrode are opposed to each other, and wherein
in the first light emitting diodes,
their anodes are connected to the protruding portions of the first electrode while their cathodes are connected to the protruding portions of the second electrode, and
in the second light emitting diodes,
their cathodes are connected to the protruding portions of the first electrode while their anodes are connected to the protruding portions of the second electrode.

11. The light emitting device as claimed in claim 1, wherein
a maximum size of the light emitting diodes is not more than 100 μm.

12. The light emitting device as claimed in claim 1, wherein
the light emitting diodes are rod-like shaped.

13. The light emitting device as claimed in claim 1, wherein
a semiconductor layer forming the light emitting diodes is connected directly to the first, second electrodes.

14. The light emitting device as claimed in claim 1, wherein
the light emitting diodes each have
a first-conductive-type core portion, and
a second-conductive-type shell portion which covers an outer peripheral surface of the first-conductive-type core portion, where
part of the outer peripheral surface of the first-conductive-type core portion is exposed from the second-conductive-type shell portion.

15. The light emitting device as claimed in claim 14, wherein
the core portion of each light emitting diode is columnar-shaped,
the shell portion of each light emitting diode covers the outer peripheral surface of the columnar-shaped core portion,
part of the outer peripheral surface of the columnar-shaped core portion is exposed from the shell portion, and
a junction surface between the columnar-shaped core portion and the shell portion is concentrically formed around the core portion.

16. A backlight for use in displays, including the light fitting device as defined in claim 1.

17. An illuminating device including the light emitting device as defined in claim 1.

18. An LED display including the light emitting device as defined in claim 1.

19. A manufacturing method for light emitting devices, comprising the steps of:
preparing a substrate having a first electrode and a second electrode;
coating the substrate with a solution containing a plurality of light emitting diodes having a maximum size of 100 μm or less; and
applying a voltage to the first electrode and the second electrode to make the light emitting diodes arrayed into positions defined by the first, second electrodes.

20. A light emitting device comprising:
a first electrode formed on a substrate;
a second electrode formed on the substrate;
a third electrode formed on the substrate; and
a rod-like light emitting element which has a first-conductive-type first region, a second-conductive-type second region, and a first-conductive-type third region and in which the first region, the second region and the third region are placed in an order of the first region, the second region and the third region, wherein
the first region is connected to one of the first electrode and the third electrode, the second region is connected to the second electrode, and the third region is connected to the other of the first electrode and the third electrode.

21. The light emitting device as claimed in claim 20, wherein
electric current is carried in either one of a first conductive direction and a second conductive direction, where the first conductive direction is a direction in which the electric current flows from one of the first electrode and the third electrode via sequentially the first region and the second region to the second electrode, and the second conductive direction is a direction in which the electric current flows from the second electrode via sequentially the second region and the first region to one of the first electrode and the third electrode, or electric current is carried in either one of a third conductive direction and a fourth conductive direction, where the third conductive direction is a direction in which the electric current flows from the other of the first electrode and the third electrode via sequentially the third region and the second region to the second electrode, and the fourth conductive direction is a direction in which the electric current flows from the second electrode via sequentially the second region and the third region to the other of the first electrode and the third electrode.

22. The light emitting device as claimed in claim 20, wherein
electric current is carried in either one of a first conductive direction and a second conductive direction, where the first conductive direction is a direction in which the electric current flows from one of the first electrode and the third electrode via sequentially the first region and the second region to the second electrode and in which the electric current flows from the other of the first electrode and the third electrode via sequentially the third region and the second region to the second electrode, and the second conductive direction is a direction in which the electric current flows from the second electrode via sequentially the second region and the first region to one of the first electrode and the third electrode and moreover in which the electric current flows from the second electrode via sequentially the second region and the third region to the other of the first electrode and the third electrode.

23. The light emitting device as claimed in claim 20, wherein
one end portion of the first region and the other end portion of the second region are joined together and moreover one end portion of the second region and the other end portion of the third region are joined together, and
the other end portion of the first region is connected to one of the first electrode and the third electrode, and moreover one end portion of the third region is connected to the other of the first electrode and the third electrode.

24. The light emitting device as claimed in claim 20, wherein
the rod-like light emitting element comprises:
a core portion in which the first region and the third region adjoin each other in a rod-like shape and moreover extend through the second region; and
a shell portion which is formed of the second region and which covers an outer peripheral surface of the core portion, wherein
the first region and the third region of the core portion are exposed from both ends of the shell portion.

25. The light emitting device as claimed in claim 20, wherein
a maximum size of the rod-like light emitting element is not more than 100 μm.

26. A backlight for use in displays, including the light emitting device as defined in claim 20.

27. An illuminating device including the light emitting device as defined in claim 20.

28. An LED display including the light emitting device as defined in claim 20.

29. A manufacturing method for light emitting devices, comprising the steps of:
preparing a substrate having a first electrode, a second electrode, and a third electrode;
coating the substrate with a solution containing a plurality of rod-like light emitting elements having a maximum size of 100 μm or less, the rod-like light emitting elements each having a first-conductive-type first region, a second-conductive-type second region, and a first-conductive-type third region, where the first region, the second region and the third region are placed in an order of the first region, the second region and the third region, and
applying a voltage to the first electrode and the third electrode to make the plurality of rod-like light emitting elements arrayed into positions defined by the first, second and third electrodes.
